(19) United States
(12) Patent Application Publication
(10) Pub. No.: US 2025/0293199 A1
(43) Pub. Date: Sep. 18, 2025

(54) SEMICONDUCTOR DEVICE

(71) Applicant: Rohm Co., Ltd., Kyoto-shi (JP)

(72) Inventors: Ryuta KIMURA, Kyoto-shi (JP); Yuto NISHIYAMA, Kyoto-shi (JP); Yosui FUTAMURA, Kyoto-shi (JP)

(21) Appl. No.: 19/222,294

(22) Filed: May 29, 2025

Related U.S. Application Data
(63) Continuation of application No. PCT/JP2023/043259, filed on Dec. 4, 2023.

(30) Foreign Application Priority Data
Dec. 5, 2022 (JP) 2022-194190
Dec. 5, 2022 (JP) 2022-194191

(51) Int. Cl. H01L 23/00; H01L 23/31; H01L 23/495; H01L 25/07; H10D 80/20

(52) U.S. Cl. CPC H01L 24/48; H01L 23/49562; H01L 23/49575; H01L 23/49582; H01L 24/49; H01L 25/072; H10D 80/251; H01L 23/3121; H01L 24/45; H01L 2224/45139; H01L 2224/45144; H01L 2224/45147; H01L 2224/45164; H01L 2224/48137; H01L 2224/48245; H01L 2224/4917; H01L 2224/49175; H01L 2924/10253; H01L 2924/13091

(57) ABSTRACT

A semiconductor device includes a first semiconductor element, a plurality of leads, a plurality of wires and a sealing resin covering the first semiconductor element, the plurality of wires, and at least a part of each of the plurality of leads. The plurality of leads include a first lead. The plurality of wires include a plurality of first wires each having a first bonding portion connected to the first semiconductor element and a second bonding portion connected to the first lead. The first lead includes a first portion extending in an x first direction. The second bonding portions of the plurality of first wires are connected to the first portion and arranged in a plurality of rows along the x direction.

### TECHNICAL FIELD

The present disclosure relates to a semiconductor device.

### BACKGROUND ART

JP-A-2022-118411 discloses an example of a conventional semiconductor device. The semiconductor device disclosed in the document includes a semiconductor element, a plurality of leads, and a sealing resin. One electrode of the semiconductor element and one lead are connected to each other via a plurality of wires.

### BRIEF DESCRIPTION OF THE DRAWINGS

FIG. 1 is a plan view of a semiconductor device according to a first embodiment of the present disclosure.

FIG. 2 is a partial plan view of the semiconductor device according to the first embodiment of the present disclosure.

FIG. 3 is a cross-sectional view taken along a line III-III of FIG. 1.

FIG. 4 is a cross-sectional view taken along a line IV-IV of FIG. 1.

FIG. 5 is a cross-sectional view taken along a line V-V of FIG. 1.

FIG. 6 is a cross-sectional view taken along a line VI-VI of FIG. 1.

FIG. 7 is a partially enlarged plan view of the semiconductor device according to the first embodiment of the present disclosure.

FIG. 8 is a partially enlarged cross-sectional view taken along a line VIII-VIII of FIG. 7.

FIG. 9 is a partially enlarged cross-sectional view taken along a line IX-IX of FIG. 7.

FIG. 10 is a partially enlarged plan view of the semiconductor device according to the first embodiment of the present disclosure.

FIG. 11 is a cross-sectional view taken along a line XI-XI of FIG. 10.

FIG. 12 is a cross-sectional view taken along a line XII-XII of FIG. 10.

FIG. 13 is a partially enlarged plan view of the semiconductor device according to the first embodiment of the present disclosure.

FIG. 14 is a cross-sectional view taken along a line XIV-XIV of FIG. 13.

FIG. 15 is a cross-sectional view taken along a line XV-XV of FIG. 13.

FIG. 16 is a partially enlarged plan view of the semiconductor device according to the first embodiment of the present disclosure.

FIG. 17 is a cross-sectional view taken along a line XVII-XVII of FIG. 16.

FIG. 18 is a cross-sectional view taken along a line XVIII-XVIII of FIG. 16.

FIG. 19 is a partially enlarged plan view of a semiconductor device according to a second embodiment of the present disclosure.

FIG. 20 is a partially enlarged plan view of the semiconductor device according to the second embodiment of the present disclosure.

FIG. 21 is a partially enlarged plan view of a semiconductor device according to a third embodiment of the present disclosure.

FIG. 22 is a partially enlarged plan view of the semiconductor device according to the third embodiment of the present disclosure.

FIG. 23 is a partially enlarged plan view of a semiconductor device according to a first variation of the third embodiment of the present disclosure.

FIG. 24 is a partially enlarged plan view of the semiconductor device according to the first variation of the third embodiment of the present disclosure.

FIG. 25 is a partially enlarged plan view of a semiconductor device according to a fourth embodiment of the present disclosure.

FIG. 26 is a partially enlarged plan view of the semiconductor device according to the fourth embodiment of the present disclosure.

FIG. 27 is a partially enlarged plan view of a semiconductor device according to a fifth embodiment of the present disclosure.

FIG. 28 is a partially enlarged plan view of the semiconductor device according to the fifth embodiment of the present disclosure.

FIG. 29 is a partially enlarged plan view of a semiconductor device according to a sixth embodiment of the present disclosure.

FIG. 30 is a partially enlarged plan view of the semiconductor device according to the sixth embodiment of the present disclosure.

FIG. 31 is a partially enlarged plan view of a semiconductor device according to a seventh embodiment of the present disclosure.

FIG. 32 is a partially enlarged plan view of the semiconductor device according to the seventh embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the expression “A surface A faces (a first side or a second side) in a direction B” is not limited to the situation where the angle of the surface A to the direction B is 90° and includes the situation where the surface A is inclined with respect to the direction B.

### First Embodiment

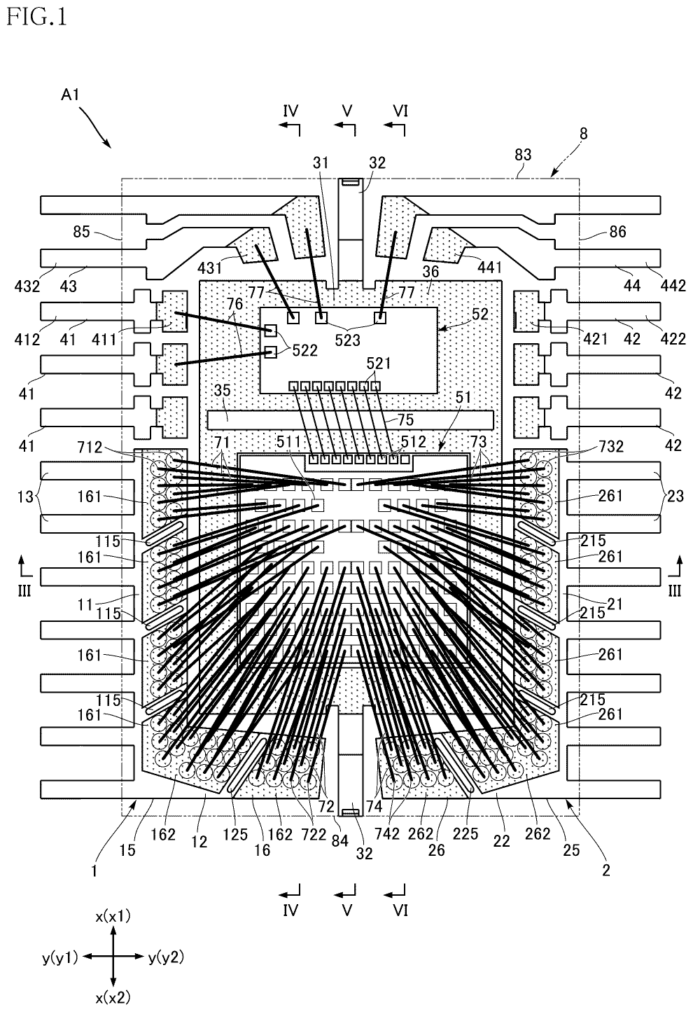

FIGS. 1 to 18 show a semiconductor device according to a first embodiment of the present disclosure. A semiconductor device A1 of the present embodiment includes a first lead 1, a second lead 2, a third lead 3, a plurality of fourth leads 41, a plurality of fifth leads 42, a plurality of sixth leads 43, a plurality of seventh leads 44, a first semiconductor element 51, a plurality of first wires 71, a plurality of second wires 72, a plurality of third wires 73, a plurality of fourth wires 74, a plurality of fifth wires 75, and a sealing resin 8.

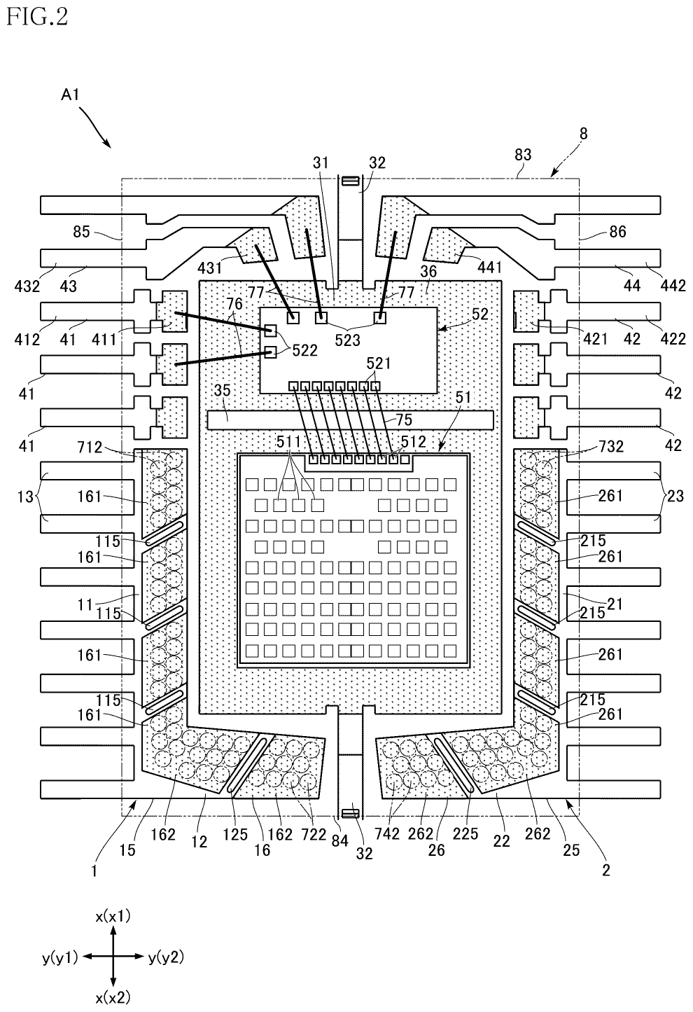

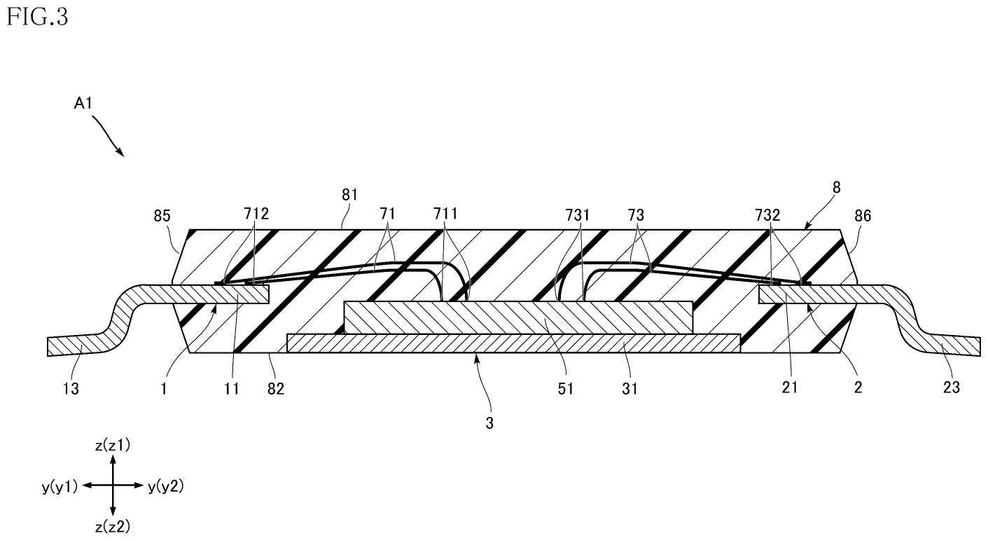

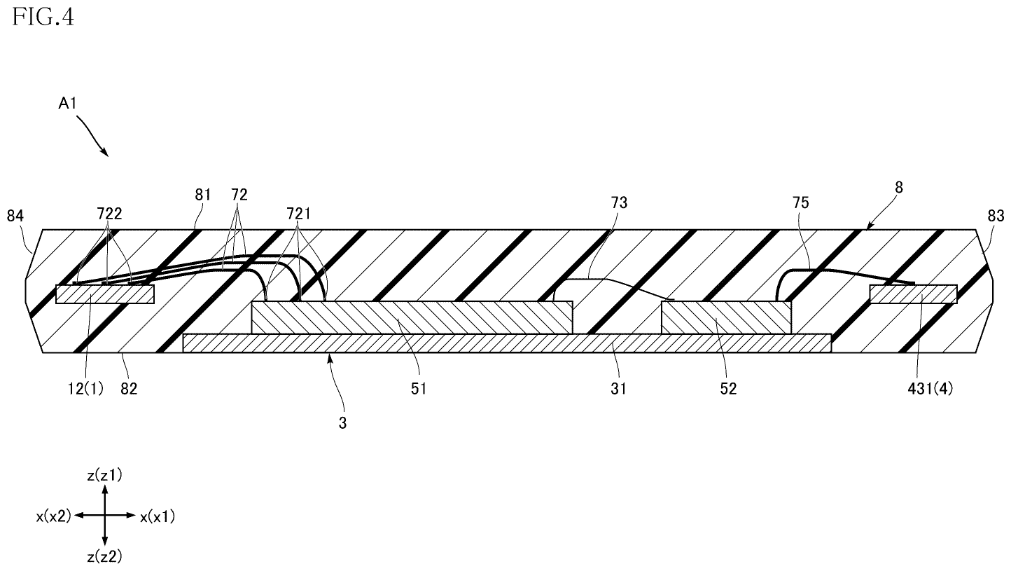

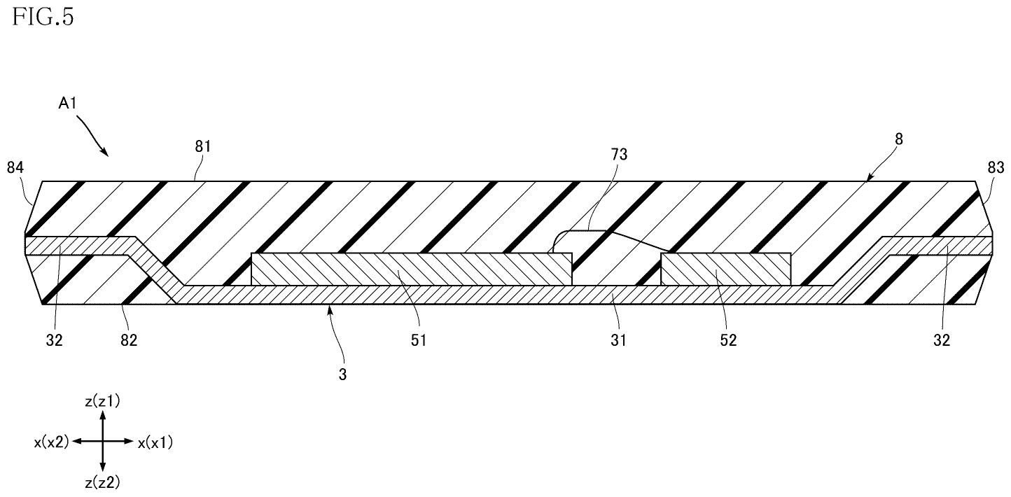

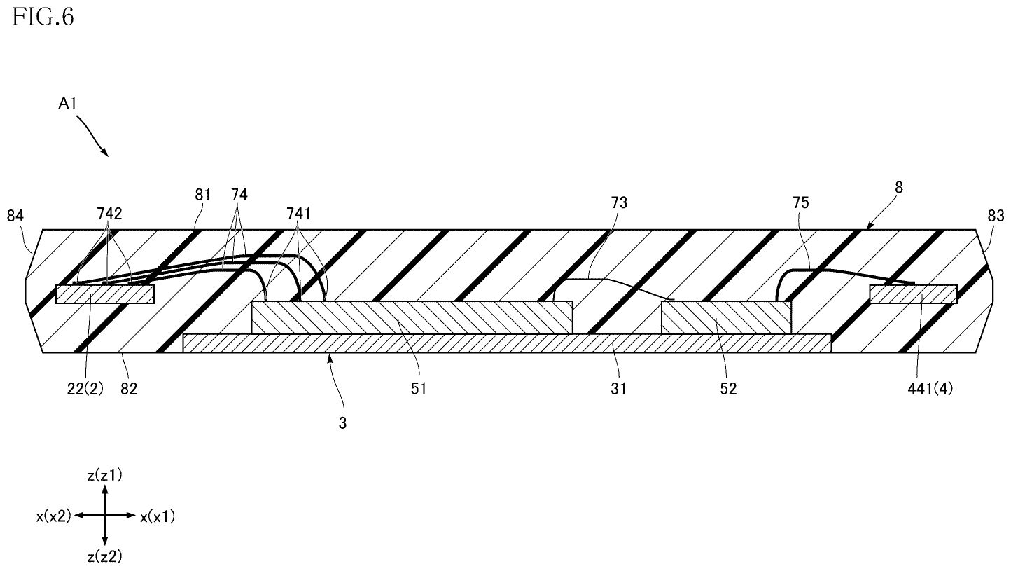

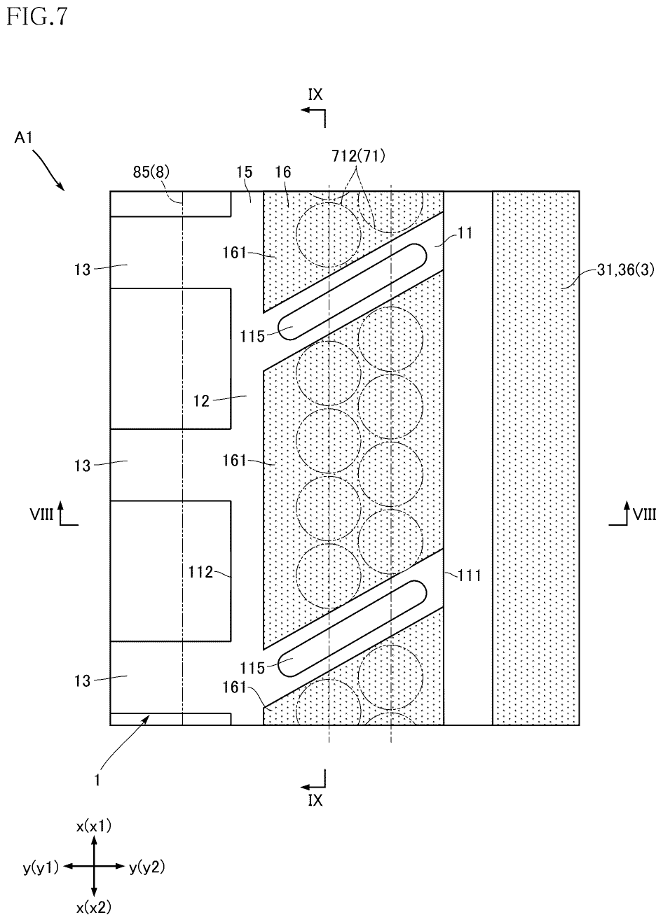

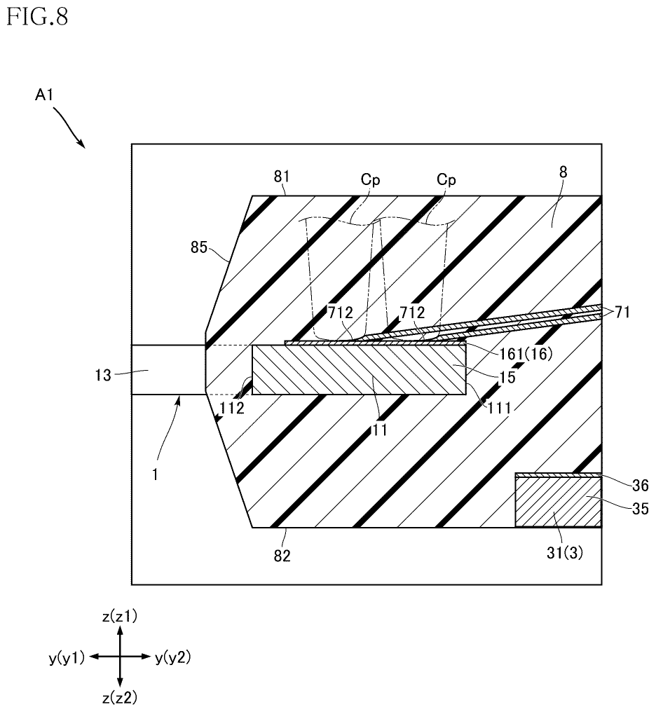

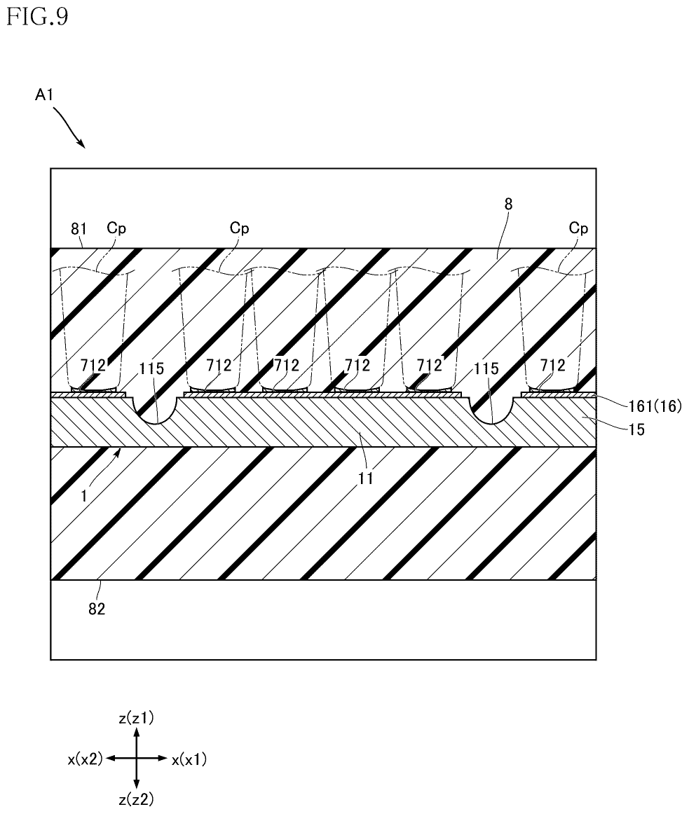

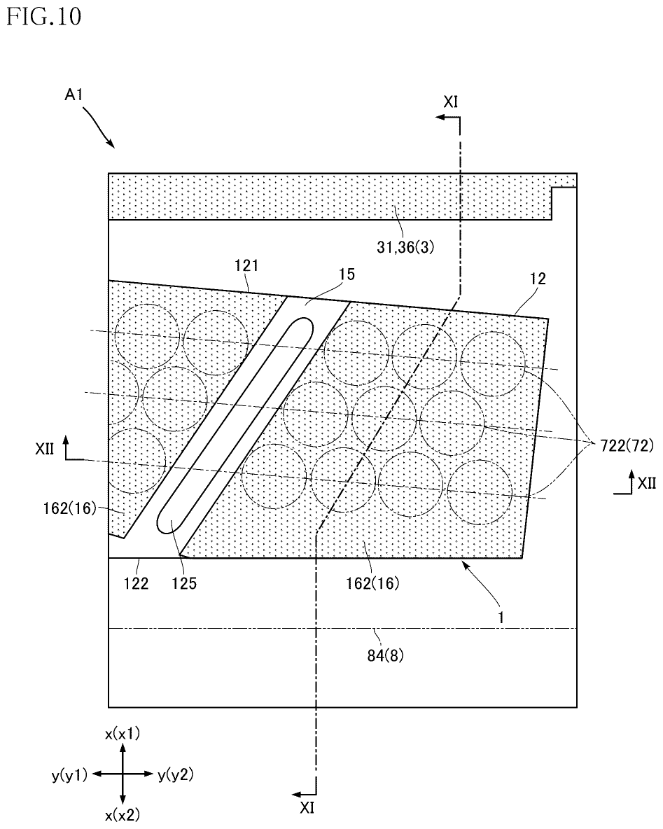

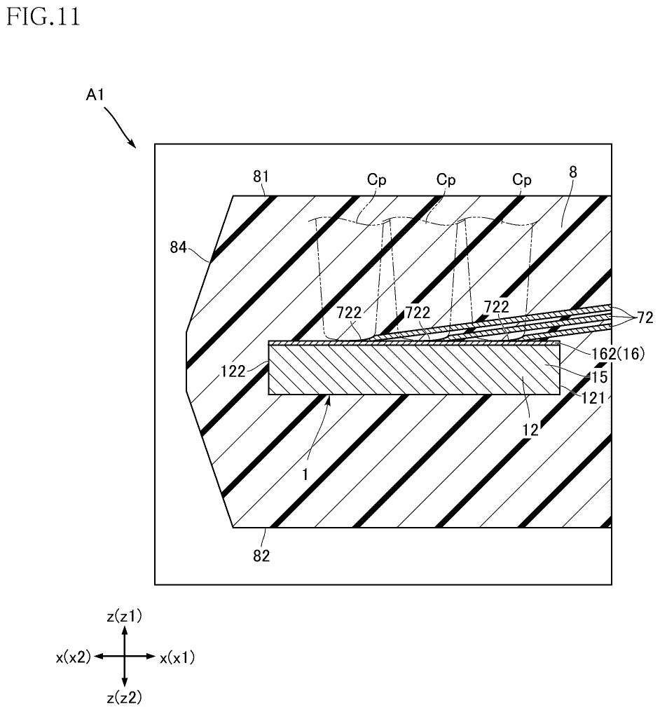

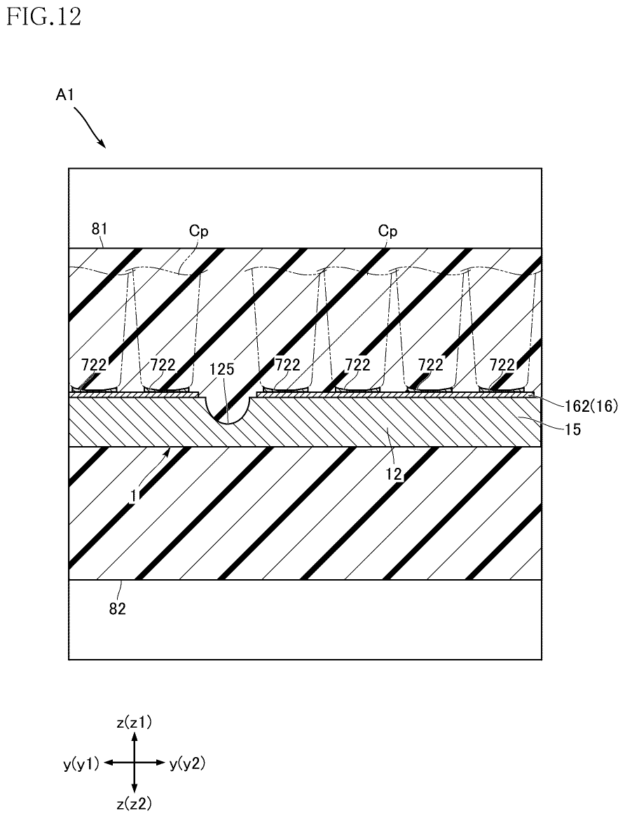

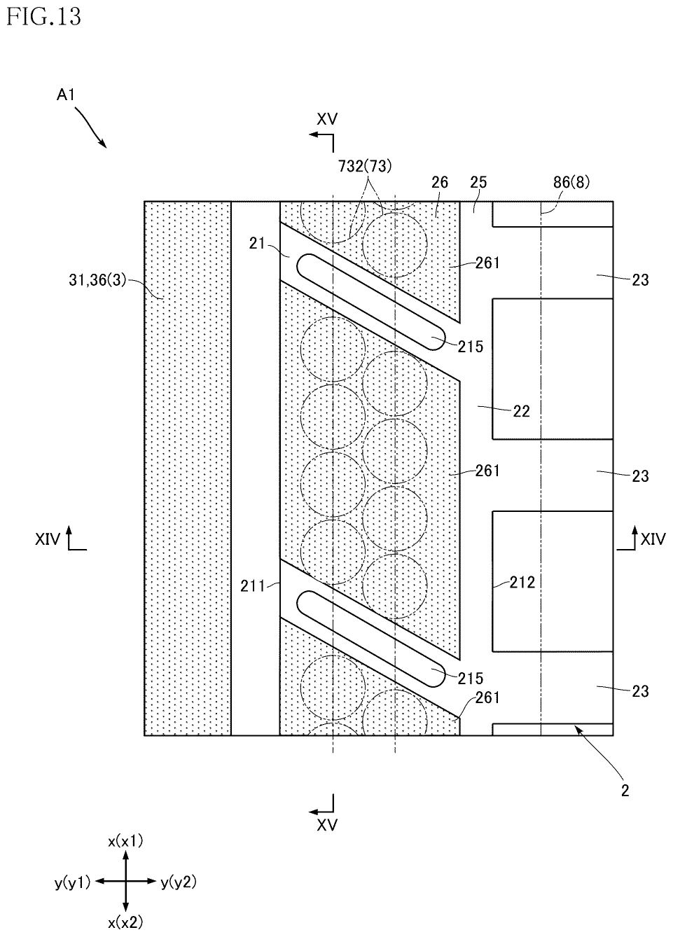

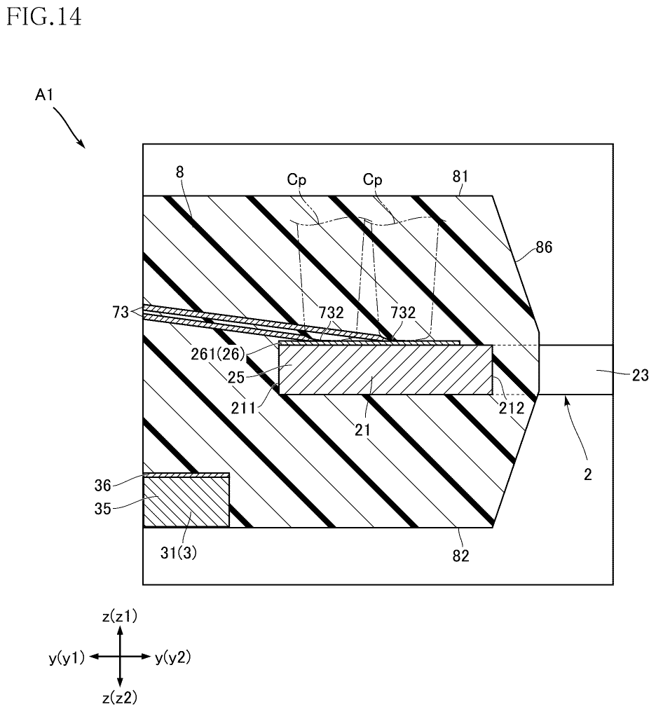

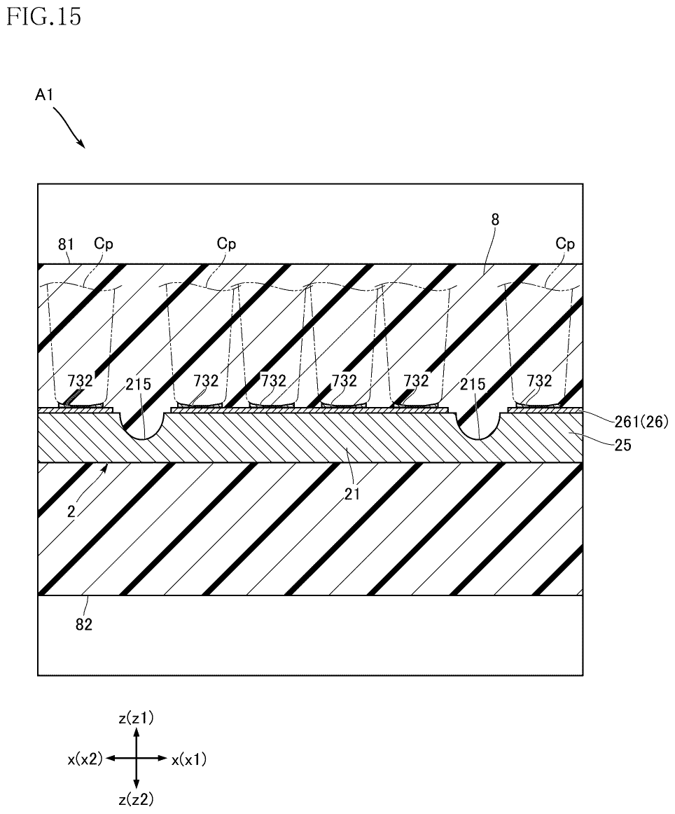

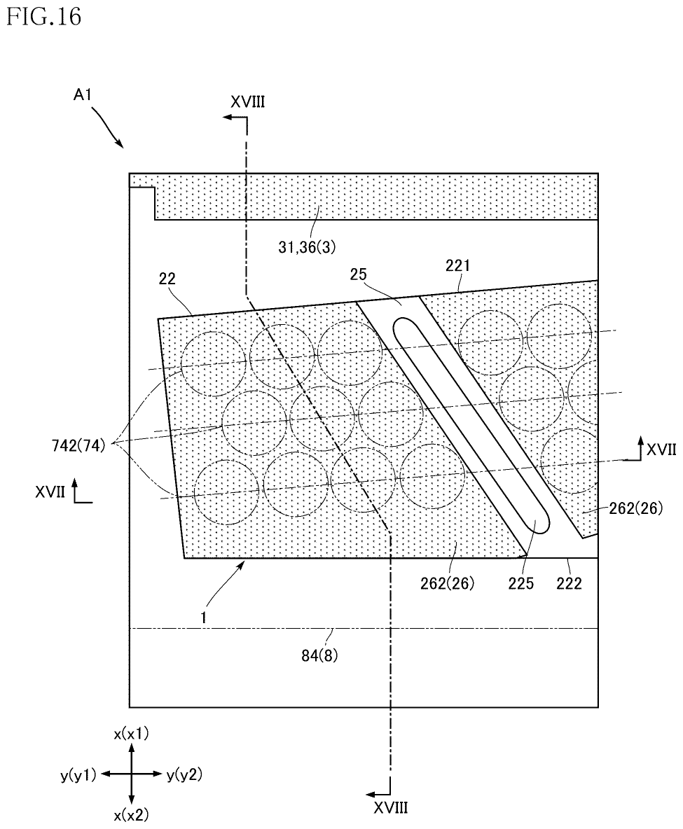

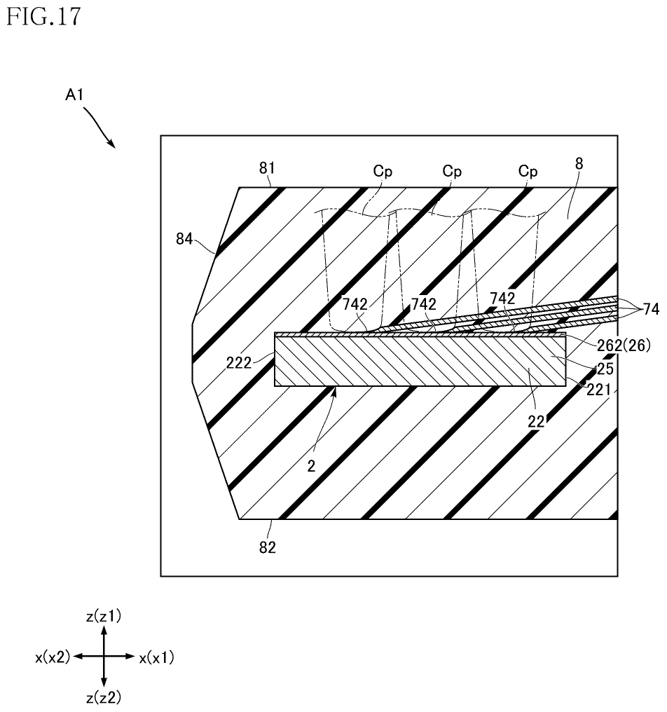

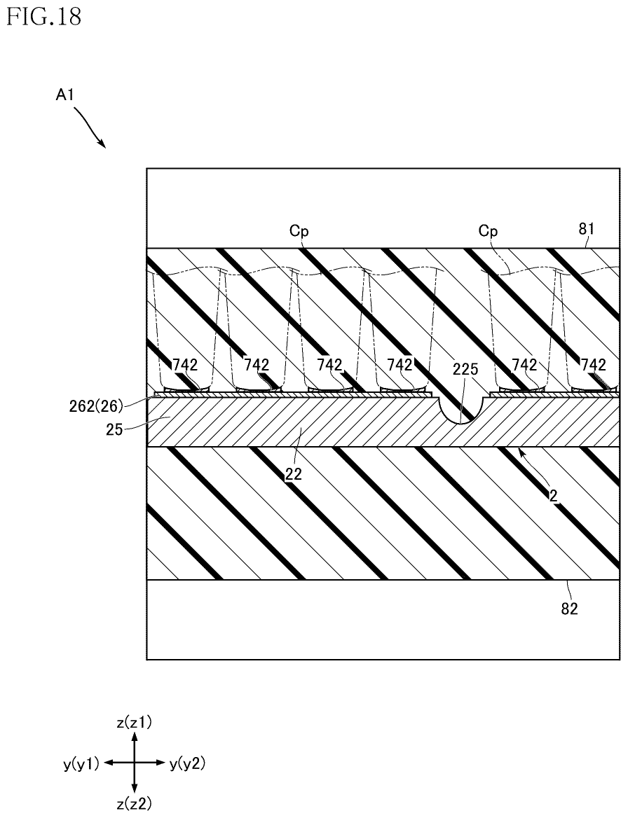

FIG. 1 is a plan view showing the semiconductor device A1. FIG. 2 is a partial plan view showing the semiconductor device A1. FIG. 3 is a cross-sectional view taken along a line III-III of FIG. 1. FIG. 4 is a cross-sectional view taken along a line IV-IV of FIG. 1. FIG. 5 is a cross-sectional view taken along a line V-V of FIG. 1. FIG. 6 is a cross-sectional view taken along a line VI-VI of FIG. 1. FIG. 7 is a partially enlarged plan view showing the semiconductor device A1. FIG. 8 is a partially enlarged cross-sectional view taken along a line VIII-VIII line of FIG. 7. FIG. 9 is a partially enlarged cross-sectional view taken along a line IX-IX of FIG. 7. FIG. 10 is a partially enlarged plan view showing the semiconductor device A1. FIG. 11 is a cross-sectional view taken along a line XI-XI of FIG. 10. FIG. 12 is a cross-sectional view taken along a line XII-XII of FIG. 10. FIG. 13 is a partially enlarged plan view showing the semiconductor device A1. FIG. 14 is a cross-sectional view taken along a line XIV-XIV of FIG. 13. FIG. 15 is a cross-sectional view taken along a line XV-XV of FIG. 13. FIG. 16 is a partially enlarged plan view showing the semiconductor device A1. FIG. 17 is a cross-sectional view taken along a line XVII-XVII of FIG. 16. FIG. 18 is a cross-sectional view taken along a line XVIII-XVIII of FIG. 16. For convenience of understanding, the first wire 71, the second wire 72, the third wire 73, and the fourth wire 74 are omitted in FIG. 2.

In these figures, three mutually orthogonal directions are referred to as appropriate. As an example, they are a thickness direction z, an x direction, which is one direction orthogonal to the thickness direction z, and a y direction, which is orthogonal to the thickness direction z and the x direction.

### First Lead 1:

The first lead 1 is a conductive member that forms part of a conductive path to the semiconductor device A1. The first lead 1 of the present embodiment includes a first base material 15 and a first metal layer 16, as shown in FIGS. 1 to 4 and 7 to 12. The first base material 15 contains a metal such as Cu (copper), Alloy 42 (iron-nickel alloy) or the like, for example. The first base material 15 is preferably made of a material that has a higher bonding strength to the sealing resin 8 than the material of the first metal layer 16. The first metal layer 16 is formed on the first base material 15 and is a plated layer containing a metal such as Ag (silver), Ni (nickel), Pd (palladium), Au (gold) or the like, for example. The first metal layer 16 is preferably made of a material that has a higher bonding strength to the first wire 71 and the second wire 72 than the material of the first base material 15. The first lead 1 includes a first portion 11, a second portion 12, and a plurality of first terminal portions 13.

The first portion 11 extends along the x direction. The x direction is an example of a “first direction”. The first portion 11 includes a first edge 111 and a second edge 112. The first edge 111 is an edge of the first portion 11 on the y2 side of the y direction and extends along the x direction. The second edge 112 is an edge of the first portion 11 on the y1 side of the y direction and extends along the x direction. The first portion 11 of the present embodiment includes a plurality of first recesses 115. The first recesses 115 are recessed in the z2 side of the z direction. The first recesses 115 are arranged at intervals along the x direction. In the illustrated example, the first recesses 115 are grooves each extending along a direction that intersects the x direction and the y direction.

The second portion 12 extends along the y direction. The second portion 12 includes a third edge 121 and a fourth edge 122. The third edge 121 is an edge of the second portion 12 on the x1 side of the x direction and is slightly inclined with respect to the y direction. The fourth edge 122 is an edge of the second portion 12 on the x2 side of the x direction and extends along the y direction.

The first metal layer 16 includes a plurality of first areas 161 and a plurality of second areas 162. The first areas 161 are formed in the first portion 11 and are arranged along the x direction. Between adjacent first areas 161, there are areas where the first metal layer 16 is not formed and the first base material 15 is exposed. In the illustrated example, the first area 161 reaches the first edge 111. The first area 161 is spaced apart from the second edge 112.

The second areas 162 are formed in the second portion 12 and are arranged along the y direction. Between adjacent second areas 162, there are areas where the first metal layer 16 is not formed and the first base material 15 is exposed. In the illustrated example, the first area 161 on the outermost x2 side of the x direction and the second area 162 on the outermost y1 side in the y direction are connected to each other. The second area 162 reaches the third edge 121. The second area 162 on the y1 side of the y direction is spaced apart from the fourth edge 122. The second area 162 on the y2 side of the y direction reaches the fourth edge 122.

The first portion 11 of the present embodiment includes the first recesses 115. The first recesses 115 are recessed in the z2 side of the z direction. The first recesses 115 are arranged at intervals along the x direction. The first recesses 115 are disposed between the respective adjacent first areas 161 in the x direction. In the illustrated example, the first recesses 115 are grooves each extending in a direction that intersects the x direction and the y direction. The side of the first area 161 facing the first recess 115 is parallel to the first recess 115.

The second portion 12 of the present embodiment includes a second recess 125. The second recess 125 is recessed in the z2 side of the z direction. The second recess 125 is located between the adjacent second areas 162 in the y direction. In the illustrated example, the second recess 125 is a groove extending in a direction that intersects the x direction and the y direction. The side of the second area 162 facing the second recess 125 is parallel to the second recess 125.

The first terminal portions 13 extend from the first portion 11 in the y1 side of the y direction and are arranged at the same pitch along the x direction. The first terminal portions 13 protrude from the sealing resin 8 in the y1 side of the y direction. In the illustrated example, the first terminal portion 13 includes a bent portion protruding from the sealing resin 8.

### Second Lead 2:

The second lead 2 is a conductive member that forms part of a conductive path to the semiconductor device A1. As shown in FIGS. 1 to 3, 6 and 13 to 18, the second lead 2 of the present embodiment is disposed on the y2 side of the y direction with respect to the first lead 1. It includes a second base material 25 and a second metal layer 26. The second base material 25 contains a metal such as Cu (copper), Alloy 42 (iron-nickel alloy) or the like, for example. The second base material 25 is preferably made of a material that has a higher bonding strength to the sealing resin 8 than the material of the second metal layer 26. The second metal layer 26 is formed on the second base material 25 and is a plated layer containing a metal such as Ag (silver), Ni (nickel), Pd (palladium), Au (gold) or the like, for example. The second metal layer 26 is preferably made of a material that has a higher bonding strength to the third wire 73 and the fourth wire 74 than the material of the second base material 25. The second lead 2 includes a third portion 21, a fourth portion 22, and a plurality of second terminal portions 23.

The third portion 21 extends along the x direction. The third portion 21 includes a fifth edge 211 and a sixth edge 212. The fifth edge 211 is an edge of the third portion 21 on the y1 side of the y direction and extends along the x direction. The sixth edge 212 is an edge of the third portion 21 on the y2 side of the y direction and extends along the x direction. The third portion 21 of the present embodiment includes a plurality of third recesses 215. The third recesses 215 are recessed in the z2 side of the z direction. The third recesses 215 are arranged at intervals along the x direction. In the illustrated example, the third recesses 215 are grooves each extending along a direction that intersects the x direction and the y direction.

The fourth portion 22 extends along the y direction. The fourth portion 22 includes a seventh edge 221 and an eighth edge 222. The seventh edge 221 is an edge of the fourth portion 22 on the x1 side of the x direction and is slightly inclined with respect to the y direction. The eighth edge 222 is an edge of the fourth portion 22 on the x2 side of the x direction and extends along the y direction.

The second metal layer 26 includes a plurality of third areas 261 and a plurality of fourth areas 262. The third areas 261 are formed on the third portion 21 and are arranged along the x direction. Between adjacent third areas 261, there are areas where the second metal layer 26 is not formed and the second base material 25 is exposed. In the illustrated example, the third area 261 reaches the fifth edge 211. The third area 261 is spaced apart from the sixth edge 212.

A plurality of fourth areas 262 are formed on the fourth portion 22 and are arranged along the y direction. Between adjacent fourth areas 262, there are areas where the second metal layer 26 is not formed and the second base material 25 is exposed. In the illustrated example, the third area 261 on the outermost x2 side of the x direction and the fourth area 262 on the outermost y2 side of the y direction are connected to each other. The fourth area 262 reaches the seventh edge 221. The fourth area 262 on the y2 side of the y direction is spaced apart from the eighth edge 222. The fourth area 262 on the y1 side of the y direction reaches the eighth edge 222.

The third portion 21 of the present embodiment includes the third recesses 215. The third recesses 215 are recessed in the z2 side of the z direction. The third recesses 215 are arranged at intervals along the x direction. The third recesses 215 are disposed between the respective adjacent third areas 261 in the x direction. In the illustrated example, the third recesses 215 are grooves each extending in a direction that intersects the x direction and the y direction. The side of the third area 261 facing the third recess 215 is parallel to the third recess 215.

The fourth portion 22 of the present embodiment includes a fourth recess 225. The fourth recess 225 is recessed in the z2 side of the z direction. The fourth recess 225 is located between the adjacent fourth areas 262 in the y direction. In the illustrated example, the fourth recess 225 is a groove extending in a direction that intersects the x direction and the y direction. The side of the fourth area 262 facing the fourth recess 225 is parallel to the fourth recess 225.

The second terminal portions 23 extend from the third portion 21 in the y2 side of the y direction and are arranged at the same pitch along the x direction. The second terminal portions 23 protrude from the sealing resin 8 in the y2 side of the y direction. In the illustrated example, the second terminal portion 23 includes a bent portion protruding from the sealing resin 8.

### Third Lead 3:

As shown in FIGS. 1 to 6, the third lead 3 is located between the first lead 1 and the second lead 2 in the y direction. The third lead 3 includes a third base material 35 and a third metal layer 36. The third base material 35 contains a metal such as Cu (copper), Alloy 42 (iron-nickel alloy) or the like, for example. The third metal layer 36 is formed on the third base material 35 and is a plated layer containing a metal such as Ag (silver), Ni (nickel), Pd (palladium), Au (gold) or the like, for example. The third lead 3 includes an island portion 31 and a pair of extending portions 32.

The island portion 31 has a rectangular shape as viewed in the z direction and is the portion on which the first semiconductor element 51 and the second semiconductor element 52 are mounted. The island portion 31 is exposed from the sealing resin 8 on the z2 side of the z direction. The pair of extending portions 32 extend from the island portion 31 in both sides of the x direction, respectively. In the illustrated example, the extending portion 32 has a bent shape as viewed in the y direction.

### Fourth Leads 41:

As shown in FIGS. 1 and 2, the fourth leads 41 are disposed on the x1 side of the x direction with respect to the first lead 1 and on the y1 side of the y direction with respect to the island portion 31. The fourth leads 41 are arranged along the x direction. The fourth lead 41 includes a pad portion 411 and a terminal portion 412. The pad portion 411 is a portion disposed on the y1 side of the y direction with respect to the island portion 31. The pad portion 411 may be provided with a metal layer, for example, similar to the first metal layer 16. The terminal portion 412 extends from the pad portion 411 in the y1 side of the y direction and protrudes from the sealing resin 8 in the y1 side of the y direction. The array pitch of the terminal portions 412 along the x direction may be the same as that of the first terminal portions 13. The portion of the terminal portion 412 protruding from the sealing resin 8 has a bent shape in the same manner as the first terminal portion 13.

### Fifth Leads 42:

As shown in FIGS. 1 and 2, the fifth leads 42 are disposed on the x1 side of the x direction with respect to the second lead 2 and on the y2 side of the y direction with respect to the island portion 31. The fifth leads 42 are arranged along the x direction. The fifth lead 42 includes a pad portion 421 and a terminal portion 422. The pad portion 421 is a portion disposed on the y2 side of the y direction with respect to the island portion 31. The pad portion 421 may be provided with a metal layer, for example, similar to the second metal layer 26. The terminal portion 422 extends from the pad portion 421 in the y2 side of the y direction and protrudes from the sealing resin 8 in the y2 side of the y direction. The array pitch of the terminal portions 422 along the x direction may be the same as that of the second terminal portions 23. The portion of the terminal portion 422 protruding from the sealing resin 8 has a bent shape in the same manner as the second terminal portion 23.

### Sixth Leads 43:

As shown in FIGS. 1 and 2, the sixth leads 43 are disposed on the x1 side of the x direction with respect to the fourth leads 41 and the island portion 31, and are disposed on the y1 side of the y direction with respect to the extending portion 32 located on the x1 side of the x direction. The sixth leads 43 are arranged along the x direction. The sixth lead 43 includes a pad portion 431 and a terminal portion 432. The pad portion 431 is a portion disposed on the x1 side of the x direction with respect to the island portion 31. The pad portion 431 may be provided with a metal layer, for example, similar to the first metal layer 16. The terminal portion 432 extends from the pad portion 431 in the y1 side of the y direction and protrudes from the sealing resin 8 in the y1 side of the y direction. The array pitch of the terminal portions 432 along the x direction may be the same as that of the first terminal portions 13 or the terminal portions 412. The portion of the terminal portions 432 protruding from the sealing resin 8 has a bent shape in the same manner as the first terminal portion 13 and the terminal portion 412.

### Seventh Leads 44:

As shown in FIGS. 1 and 2, the seventh leads 44 are disposed on the x1 side of the x direction with respect to the fifth leads 42 and the island portion 31, and are disposed on the y2 side of the y direction with respect to the extending portion 32 located on the x1 side of the x direction. The seventh leads 44 are arranged along the x direction. The seventh lead 44 includes a pad portion 441 and a terminal portion 442. The pad portion 441 is a portion disposed on the x1 side of the x direction with respect to the island portion 31. The pad portion 441 may be provided with a metal layer, for example, similar to the second metal layer 26. The terminal portion 442 extends from the pad portion 441 in the y2 side of the y direction and protrudes from the sealing resin 8 in the y2 side of the y direction. The array pitch of the terminal portions 442 along the x direction may be the same as that of the second terminal portions 23 or the terminal portions 422. The portion of the terminal portions 442 protruding from the sealing resin 8 has a bent shape in the same manner as the second terminal portion 23 and the terminal portion 422.

### First Semiconductor Element 51:

The first semiconductor element 51 is an element to perform a main electrical function of the semiconductor device A1. The type of the first semiconductor element 51 is not limited, and in the present embodiment, it is a switching element, for example, a Si-MOSFET (Metal-Oxide-Semiconductor Field-Effect Transistor). The first semiconductor element 51 includes a first electrode 511 and a plurality of second electrodes 512. The first electrode 511 is, for example, a source electrode. The second electrodes 512 include, for example, a gate electrode and a source sense electrode. The first semiconductor element 51 includes a drain electrode (not shown) on the z2 side of the z direction. This drain electrode is conductively bonded to the island portion 31 (the third metal layer 36), hence the first semiconductor element 51 being mounted on the island portion 31.

The first electrode 511 may be an electrode with an integrated structure that occupies most of the first semiconductor element 51 as viewed in the z direction, or may include a plurality of discretely arranged electrodes as viewed in the z direction. The discretely arranged electrodes correspond to electrodes that are intentionally arranged without a significant concentration in any one area, and are, for example, arranged in a matrix pattern. FIG. 2 shows an example in which a plurality of first electrodes 511 are discretely arranged.

The second electrodes 512 are disposed on the x1 side of the x direction with respect to the first electrode 511. The second electrodes 512 are arranged along the y direction.

### Second Semiconductor Element 52:

The second semiconductor element 52 functions, for example, as a gate driver IC to control the first semiconductor element 51. The second semiconductor element 52 is mounted on the island portion 31 and is disposed on the x1 side of the x direction with respect to the first semiconductor element 51. In the illustrated example, as viewed in the z direction, the second semiconductor element 52 has an elongated rectangular shape and is smaller than the first semiconductor element 51. The second semiconductor element 52 includes a plurality of electrodes 521, a plurality of electrodes 522, and a plurality of electrodes 523.

### First Wires 71:

The first wires 71 are connected to the first electrode 511 of the first semiconductor element 51 and the first portion 11 of the first lead 1. The specific configuration of the first wire 71 is particularly not limited. For example, it includes a core material containing Cu (copper) and is coated with Pd (palladium). Other core materials containing Au (gold), Ag (silver), or the like may be applied for the first wire 71.

As shown in FIG. 3, the first wire 71 includes a first bonding portion 711 and a second bonding portion 712. When the first wire 71 is formed by ball bonding using a capillary Cp shown by imaginary lines in FIGS. 8 and 9, the first bonding portion 711 corresponds to a ball portion. The second bonding portion 712 corresponds to a flattened portion, which is formed as a result of being pushed and spread against a connection object to be bonded by the capillary Cp. In the present embodiment, the first bonding portions 711 of the first wires 71 are individually connected to the first electrodes 511. The second bonding portions 712 are connected to the respective first areas 161 of the first metal layer 16.

As shown in FIGS. 7 to 9, the second bonding portions 712 are arranged in a plurality of rows along the x direction. In FIG. 7, the first wires 71 are omitted, and the portions where the second bonding portions 712 can be formed are shown as circular imaginary lines. The imaginary lines may remain, for example, as a trace where the capillary Cp was pressed. In the illustrated example, the second bonding portions 712 are arranged in two rows. The second bonding portions 712 are arranged in a staggered manner. For example, when the wire diameter of the first wire 71 is 50 μm, the array pitch of the second bonding portions 712 along the x direction is, for example, about 206 μm. The pitch of the second bonding portions 712 that are diagonally adjacent to each other in different rows in the figure is also about 206 μm. In other words, the three adjacent second bonding portions 712 are each positioned at a corner of an equilateral triangle.

As shown in FIGS. 1 and 7, the extension direction of the first recess 115 coincides (or generally coincides) with the extension direction of the first wire 71 that is adjacent to the relevant first recess 115, as viewed in the z direction.

### Second Wires 72:

The second wires 72 are connected to the first electrode 511 of the first semiconductor element 51 and the second portion 12 of the first lead 1. The specific configuration of the second wire 72 is particularly not limited. For example, it includes a core material containing Cu (copper) and is coated with Pd (palladium). Other core materials containing Au (gold), Ag (silver), or the like may be applied for the second wire 72.

As shown in FIG. 4, the second wire 72 includes a first bonding portion 721 and a second bonding portion 722. When the second wire 72 is formed by ball bonding using a capillary Cp shown by imaginary lines in FIGS. 11 and 12, the first bonding portion 721 corresponds to a ball portion. The second bonding portion 722 corresponds to a flattened portion, which is formed as a result of being pushed and spread against a connection object by the capillary Cp. In the present embodiment, the first bonding portions 721 of the second wires 72 are individually connected to the first electrodes 511. The second bonding portions 722 are connected to the respective second areas 162 of the first metal layer 16.

As shown in FIGS. 10 to 12, the second bonding portions 722 are arranged in a plurality of rows along a direction slightly inclined with respect to the y direction. This slightly inclined direction is an example of a “second direction”. In FIG. 10, the second wires 72 are omitted, and the portions where the second bonding portions 722 can be formed are shown as circular imaginary lines. The imaginary lines may remain, for example, as a trace where the capillary Cp was pressed. In the illustrated example, the second bonding portions 722 are arranged in three rows. The second bonding portions 722 are arranged in a staggered manner. For example, when the wire diameter of the second wire 72 is 50 μm, the array pitch of the second bonding portions 722 along the x direction is about 206 μm. The pitch of the second bonding portions 722 that are diagonally adjacent to each other in different rows in the figure is also about 206 μm. In other words, the three adjacent second bonding portions 722 are each positioned at a corner of an equilateral triangle.

As shown in FIGS. 1 and 10, the extension direction of the second recess 125 coincides (or generally coincides) with the extension direction of the second wire 72 that is adjacent to the relevant second recess 125, as viewed in the z direction.

### Third Wires 73:

The third wires 73 are connected to the first electrode 511 of the first semiconductor element 51 and the third portion 21 of the second lead 2. The specific configuration of the third wire 73 is particularly not limited. For example, it includes a core material containing Cu (copper) and is coated with Pd (palladium). Other core materials containing Au (gold), Ag (silver), or the like may be applied for the third wire 73.

As shown in FIG. 3, the third wire 73 includes a first bonding portion 731 and a second bonding portion 732. When the third wire 73 is formed by ball bonding using a capillary Cp shown by imaginary lines in FIGS. 14 and 15, the first bonding portion 731 corresponds to a ball portion. The second bonding portion 732 corresponds to a flattened portion, which is formed as a result of being pushed and spread against a connection object by the capillary Cp. In the present embodiment, the first bonding portions 731 of the third wires 73 are individually connected to the first electrodes 511. The second bonding portions 732 are connected to the respective third areas 261 of the second metal layer 26.

As shown in FIGS. 13 to 15, the second bonding portions 732 are arranged in a plurality of rows along the x direction. In FIG. 13, the third wires 73 are omitted, and the portions where the second bonding portions 732 can be formed are shown as circular imaginary lines. The imaginary lines may remain, for example, as a trace where the capillary Cp was pressed. In the illustrated example, the second bonding portions 732 are arranged in two rows. The second bonding portions 732 are arranged in a staggered manner. For example, when the wire diameter of the third wire 73 is 50 μm, the array pitch of the second bonding portions 732 along the x direction is about 206 μm. The pitch of the second bonding portions 732 that are diagonally adjacent to each other in different rows in the figure is also about 206 μm. In other words, the three adjacent second bonding portions 732 are each positioned at a corner of an equilateral triangle.

As shown in FIGS. 1 and 13, the extension direction of the third recess 215 coincides (or generally coincides) with the extension direction of the third wire 73 that is adjacent to the relevant third recess 215, as viewed in the z direction.

### Fourth Wires 74:

The fourth wires 74 are connected to the first electrode 511 of the first semiconductor element 51 and the fourth portion 22 of the second lead 2. The specific configuration of the fourth wire 74 is particularly not limited. For example, it includes a core material containing Cu (copper) and is coated with Pd (palladium). Other core materials containing Au (gold), Ag (silver), or the like may be applied for the fourth wire 74.

As shown in FIG. 6, the fourth wire 74 includes a first bonding portion 741 and a second bonding portion 742. When the fourth wire 74 is formed by ball bonding using a capillary Cp shown by imaginary lines in FIGS. 17 and 18, the first bonding portion 741 corresponds to a ball portion. The second bonding portion 742 corresponds to a flattened portion, which is formed as a result of being pushed and spread against a connection object by the capillary Cp. In the present embodiment, the first bonding portions 741 of the fourth wires 74 are individually connected to the first electrodes 511. The second bonding portions 742 are connected to the respective fourth areas 262 of the second metal layer 26.

As shown in FIGS. 16 to 18, the second bonding portions 742 are arranged in a plurality of rows along a direction slightly inclined with respect to the y direction. This slightly inclined direction is an example of a “third direction”. In FIG. 16, the fourth wires 74 are omitted, and the areas where the second bonding portions 742 can be formed are shown as circular imaginary lines. The imaginary lines may remain, for example, as a trace of the capillary Cp was pressed. In the illustrated example, the second bonding portions 742 are arranged in three rows. The second bonding portions 742 are arranged in a staggered manner. For example, when the wire diameter of the fourth wire 74 is 50 μm, the array pitch of the second bonding portions 742 along the x direction is about 206 μm. The pitch of the second bonding portions 742 that are diagonally adjacent to each other in different rows in the figure is also about 206 μm. In other words, the three adjacent second bonding portions 742 are each positioned at a corner of an equilateral triangle.

As shown in FIGS. 1 and 16, the extension direction of the fourth recess 225 coincides (or generally coincides) with the extension direction of the fourth wire 74 that is adjacent to the relevant fourth recess 225, as viewed in the z direction.

In FIG. 1, the first wire 71, the second wire 72, the third wire 73, and the fourth wire 74, which are shown to overlap with another, are prevented from interfering with each other, for example by varying their heights in the z direction. However, in the present embodiment, even if any of the first wire 71, the second wire 72, the third wire 73 and the fourth wire 74 comes into contact with another, the semiconductor device A1 can still perform its electrical function, since all of them are connected to the first electrode 511.

### Fifth Wires 75:

As shown in FIGS. 1, 2 and 4, the fifth wires 75 are individually connected to the second electrodes 512 of the first semiconductor element 51 and the electrodes 521 of the second semiconductor element 52. The fifth wire 75 contains, for example, Au (gold), Cu (copper), or the like.

### Sixth Wires 76:

As shown in FIGS. 1, 2 and 4, the sixth wires 76 are individually connected to the electrodes 522 of the second semiconductor element 52 and the pad portions 411 of the fourth leads 41. The sixth wire 76 contains, for example, Au (gold), Cu (copper), or the like.

### Seventh Wires 77:

As shown in FIGS. 1, 2 and 4, the seventh wires 77 are individually connected to the electrodes 523 of the second semiconductor element 52 and the pad portions 431 of the sixth leads 43 or the pad portions 441 of the seventh leads 44. The seventh wire 77 contains, for example, Au (gold), Cu (copper), or the like.

### Sealing Resin 8:

The sealing resin 8 covers the first semiconductor element 51, the second semiconductor element 52, the first wires 71, the second wires 72, the third wires 73, the fourth wires 74, the fifth wires 75, and a part of each of the first lead 1, the second lead 2, the third lead 3, the fourth leads 41, the fifth leads 42, the sixth leads 43, and the seventh leads 44. The material of the sealing resin 8 is particularly not limited, and is made of a black epoxy resin, for example.

As shown in FIGS. 1 to 6, the sealing resin 8 includes a first resin surface 81, a second resin surface 82, a third resin surface 83, a fourth resin surface 84, a fifth resin surface 85, and a sixth resin surface 86.

The first resin surface 81 faces the z1 side of the z direction and is flat in the illustrated example. The second resin surface 82 faces the z2 side of the z direction and is flat in the illustrated example.

The third resin surface 83 faces the x1 side of the x direction and is bent in the illustrated example. The fourth resin surface 84 faces the x2 side of the x direction and is bent in the illustrated example.

The fifth resin surface 85 faces the y1 side of the y direction and is bent in the illustrated example. From the fifth resin surface 85 protrude the first terminal portions 13, the terminal portions 412 and the terminal portions 432. The sixth resin surface 86 faces the y2 side of the y direction and is bent in the illustrated example. From the sixth resin surface 86 protrude the second terminal portions 23, the terminal portions 422 and the terminal portions 442.

Next, the operative effects of the semiconductor device A1 are as follows.

According to the present embodiment, the second bonding portions 712 are arranged in a plurality of rows, as shown in FIG. 7. This makes it possible to increase the number of the first wires 71 that can be connected to the first portion 11 of the first lead 1 of the same size. Therefore, it is possible to achieve a high current in the semiconductor device A1.

The first wires 71 are arranged in a staggered manner. This is suitable for increasing the number of the first wires 71.

The second bonding portions 722 are arranged in a plurality of rows, as shown in FIG. 10. This makes it possible to increase the number of the second wires 72 that can be connected to the second portion 12 of the first lead 1 of the same size. Therefore, it is possible to achieve a high current in the semiconductor device A1.

The second wires 72 are arranged in a staggered manner. This is suitable for increasing the number of the second wires 72. The second wires 72 are arranged in three rows. This further increases the number of the second wires 72.

The second bonding portions 732 are arranged in a plurality of rows, as shown in FIG. 13. This makes it possible to increase the number of the third wires 73 that can be connected to the third portion 21 of the second lead 2 of the same size. Therefore, it is possible to further increase the current in the semiconductor device A1.

The third wires 73 are arranged in a staggered manner. This is suitable for increasing the number of the third wires 73.

The second bonding portions 742 are arranged in a plurality of rows, as shown in FIG. 16. This makes it possible to increase the number of the fourth wires 74 that can be connected to the fourth portion 22 of the second lead 2 of the same size. Therefore, it is possible to further increase the current in the semiconductor device A1.

The fourth wires 74 are arranged in a staggered manner. This is suitable for increasing the number of the fourth wires 74. The fourth wires 74 are arranged in three rows. This further increases the number of the fourth wires 74.

As viewed in the z direction, the first bonding portions 711, the first bonding portions 721, the first bonding portions 731 and the first bonding portions 741 are discretely arranged in a matrix pattern or the like, as shown in FIG. 2. This enables the first bonding portions 711, the first bonding portions 721, the first bonding portions 731 and the first bonding portions 741 to be arranged more evenly without a concentration on the first semiconductor element 51, which is preferable for achieving a high current in the semiconductor device A1.

The second bonding portions 712 are connected to the first area 161, as shown in FIG. 7. This can increase the bonding strength between the first wires 71 and the first lead 1. In addition, between adjacent first areas 161, there are areas where the first metal layer 16 is not provided and the first base material 15 is exposed. Such an area can increase the bonding strength between the first lead 1 and the sealing resin 8. Therefore, it is possible to suppress peeling of the first wire 71 and the sealing resin 8 from the first lead 1.

The second bonding portions 722 are connected to the second area 162, as shown in FIG. 10. This can increase the bonding strength between the second wires 72 and the first lead 1. In addition, between the adjacent second areas 162, there are areas where the first metal layer 16 is not provided and the first base material 15 is exposed. Such an area can increase the bonding strength between the first lead 1 and the sealing resin 8. Therefore, it is possible to suppress peeling of the second wire 72 and the sealing resin 8 from the first lead 1.

The second bonding portions 732 are connected to the third area 261, as shown in FIG. 13. This can increase the bonding strength between the third wires 73 and the second lead 2. In addition, between adjacent third areas 261, there are areas where the second metal layer 26 is not provided and the second base material 25 is exposed. Such an area can increase the bonding strength between the second lead 2 and the sealing resin 8. Therefore, it is possible to suppress peeling of the third wire 73 and the sealing resin 8 from the second lead 2.

The second bonding portions 742 are connected to the fourth area 262, as shown in FIG. 16. This can increase the bonding strength between the fourth wires 74 and the second lead 2. In addition, between adjacent fourth areas 262, there are areas where the second metal layer 26 is not provided and the second base material 25 is exposed. Such an area can increase the bonding strength between the second lead 2 and the sealing resin 8. Therefore, it is possible to suppress peeling of the fourth wire 74 and the sealing resin 8 from the second lead 2.

The first recess 115 is provided between adjacent first areas 161, as shown in FIG. 7. This can further increase the bonding strength between the first lead 1 and the sealing resin 8. The first recess 115 is a groove, which is suitable for forming the first recess 115 with a large area between adjacent first areas 161. Such an effect is similar for the third recess 215 in the second lead 2.

The second recess 125 is provided between adjacent second areas 162, as shown in FIG. 10. This can further increase the bonding strength between the first lead 1 and the sealing resin 8. The second recess 125 is a groove, which is suitable for forming the second recess 125 with a larger area between adjacent second areas 162. Such an effect is similar for the fourth recess 225 in the second lead 2.

The first area 161 reaches the first edge 111, as shown in FIG. 7. This allows the second bonding portion 712 to be disposed proximate to the island portion 31, which is advantageous for reducing the length of the first wire 71. On the other hand, the first area 161 is spaced apart from the second edge 112. Hence, the first area 161 includes an area where the first base material 15 is exposed on the y1 side of the y direction. This can increase the bonding strength between the first lead 1 and the sealing resin 8. Such an effect is similar for the relationship between the third area 261 and the fifth edge 211 or the sixth edge 212 in the second lead 2.

The second area 162 reaches the third edge 121, as shown in FIG. 10. This allows the second bonding portion 722 to be disposed proximate to the island portion 31, which is advantageous for reducing the length of the second wire 72. On the other hand, the second area 162 is spaced apart from the fourth edge 122. Hence, the second area 162 includes an area where the first base material 15 is exposed on the x2 side of the x direction. This can increase the bonding strength between the first lead 1 and the sealing resin 8. Such an effect is similar for the relationship between the fourth area 262 and the seventh edge 221 or eighth edge 222 in the second lead 2.

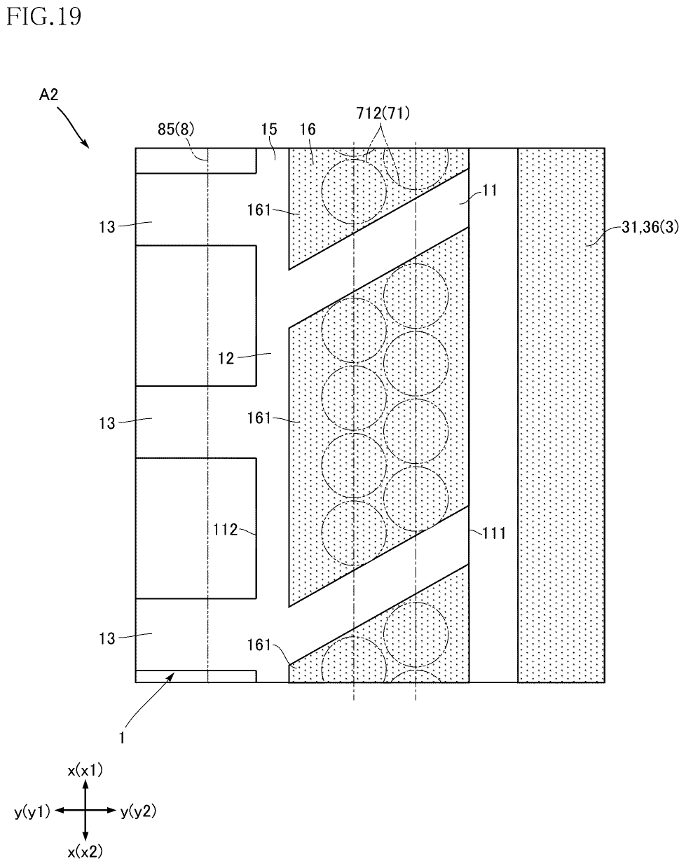

FIGS. 19 to 28 show other embodiments of the present disclosure. In these figures, identical or similar elements are denoted by the same reference signs. Various parts of embodiments and variations may be selectively used in any appropriate combination as long as it is technically compatible.

### Second Embodiment

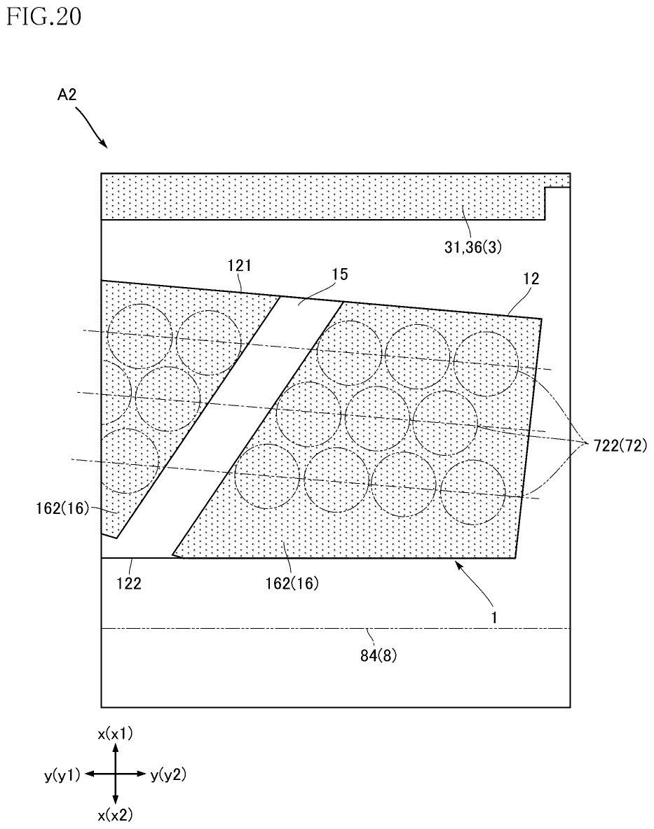

FIGS. 19 and 20 show a semiconductor device according to a second embodiment of the present disclosure. In a semiconductor device A2 of the present embodiment, the first portion 11 is not provided with the first recess 115. Also, the second portion 12 is not provided with the second recess 125. Similarly, the third portion 21 may not be provided with the third recess 215, and the fourth portion 22 may not be provided with the fourth recess 225.

The present embodiment also can achieve a high current in the semiconductor device A2. Further, it is possible to suppress peeling of the first wire 71, the second wire 72, the third wire 73, the fourth wire 74, and the sealing resin 8 from the first lead 1 and the second lead 2. As understood from the present embodiment, the first recess 115, the second recess 125, the third recess 215, and the fourth recess 225 may or may not be formed as appropriate.

### Third Embodiment

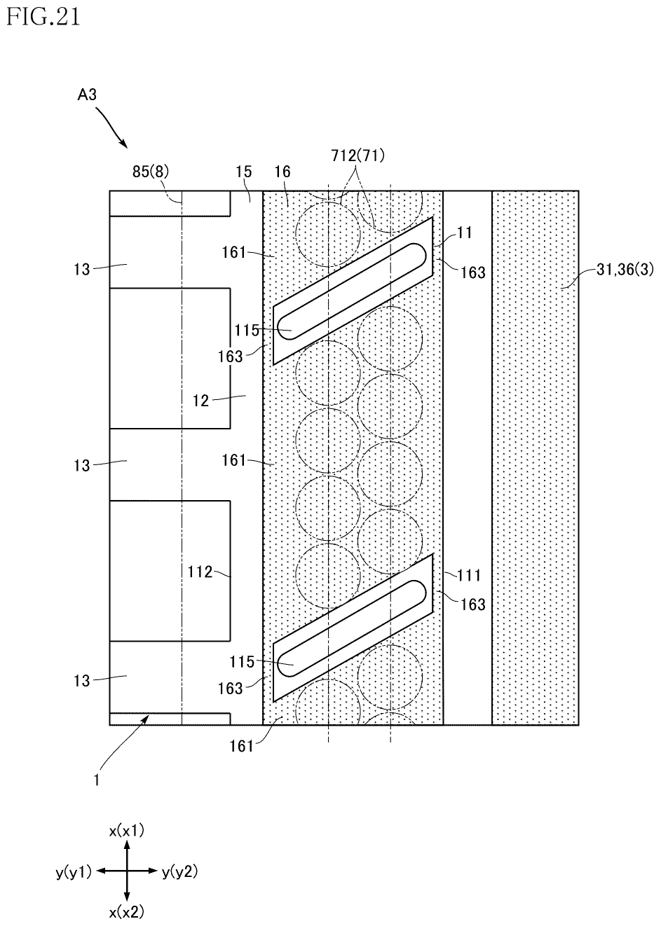

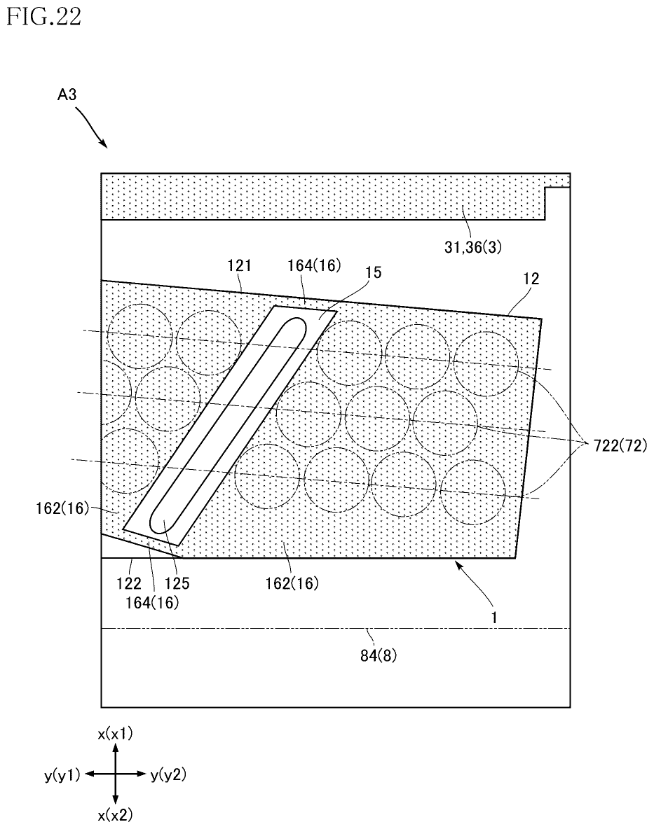

FIGS. 21 and 22 show a semiconductor device according to a third embodiment of the present disclosure. A semiconductor device A3 differs from the embodiment described above in the configuration of the first metal layer 16.

As shown in FIG. 21, the first metal layer 16 of the present embodiment includes a plurality of first connection areas 163. The first connection areas 163 couples adjacent first areas 161. In the illustrated example, two first connection areas 163 are disposed on both sides of the first recess 115 in the y direction. The first connection area 163 couples adjacent first areas 161 at their ends on either the y1 side or the y2 side in the y direction.

As shown in FIG. 22, the first metal layer 16 of the present embodiment includes a plurality of second connection areas 164. The second connection areas 164 couple adjacent second areas 162. In the illustrated example, two second connection areas 164 are disposed on both sides of the second recess 125 in the x direction. The second connection area 164 couples adjacent second areas 162 at their ends on either the x1 side or the x2 side in the x direction.

The present embodiment also can achieve a high current in the semiconductor device A3. Further, it is possible to suppress peeling of the first wire 71, the second wire 72, the third wire 73, the fourth wire 74, and the sealing resin 8 from the first lead 1 and the second lead 2. As understood from the present embodiment, the first areas 161 arranged along the x direction may be partially connected by the first connection area 163. An area where the first metal layer 16 is not provided and the first base material 15 is exposed between adjacent first areas 161 can achieve the expected effect of preventing peeling of the sealing resin 8 from the first lead 1. The second areas 162 arranged along the y direction may be partially connected by the second connection area 164. An area where the first metal layer 16 is not provided and the first base material 15 is exposed between adjacent second areas 162 can achieve the expected effect of preventing peeling of the sealing resin 8 from the first lead 1. These points are similar for the third area 261 and the fourth area 262.

### Third Embodiment First Variation

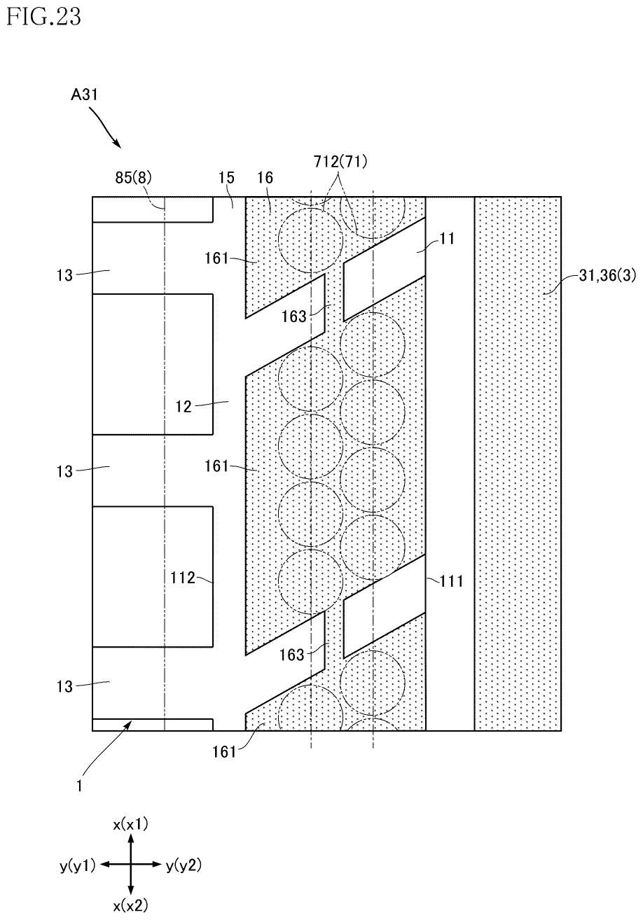

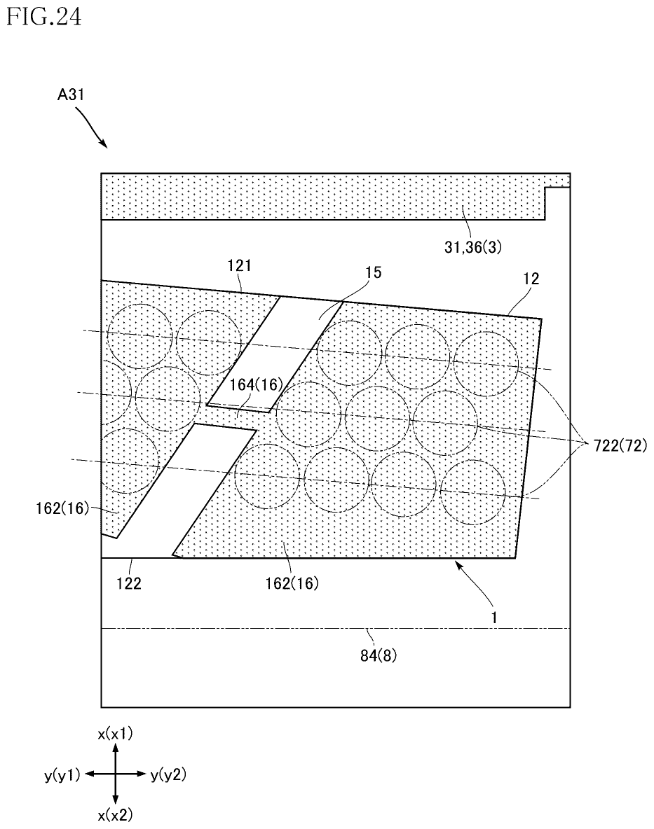

FIGS. 23 and 24 show a first variation of the semiconductor device A3. In a semiconductor device A31 of the present variation, adjacent first areas 161 are coupled through a single first connection area 163, as shown in FIG. 23. The first connection area 163 is connected to the center (or substantially the center) of the first area 161 in the y direction. The first portion 11 is not provided with the first recess 115. Adjacent second areas 162 are coupled through a single second connection area 164, as shown in FIG. 24. The second connection area 164 is connected to the center (or substantially the center) of the first area 161 in the x direction. The second portion 12 is not provided with the second recess 125.

The present variation can also achieve a high current in the semiconductor device A31. Further, it is possible to suppress peeling of the first wire 71, the second wire 72, the third wire 73, the fourth wire 74, and the sealing resin 8 from the first lead 1 and the second lead 2. As understood from the present variation, the number and arrangement of the first connection area 163 and the second connection area 164 are particularly not limited.

### Fourth Embodiment

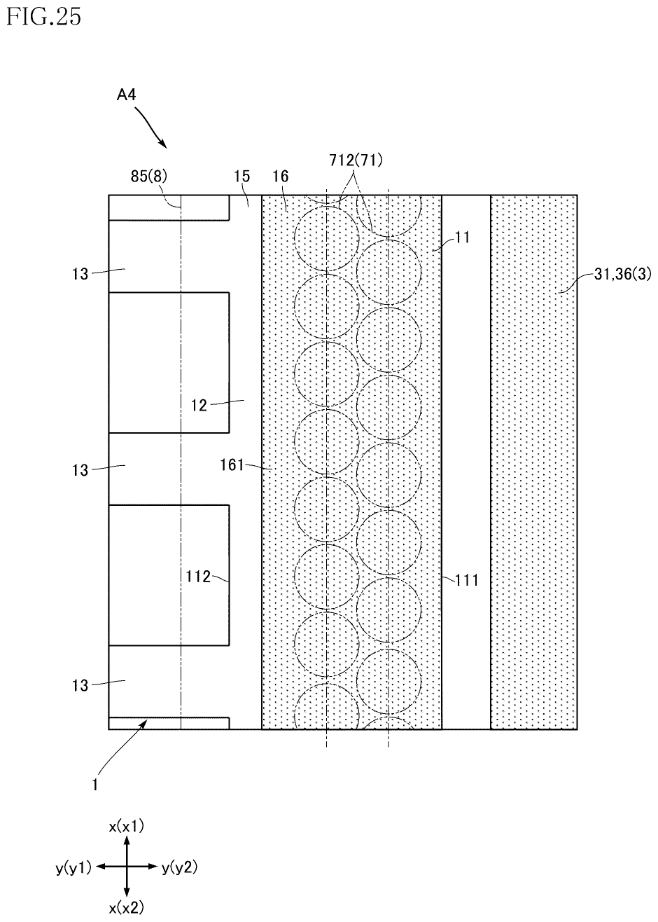

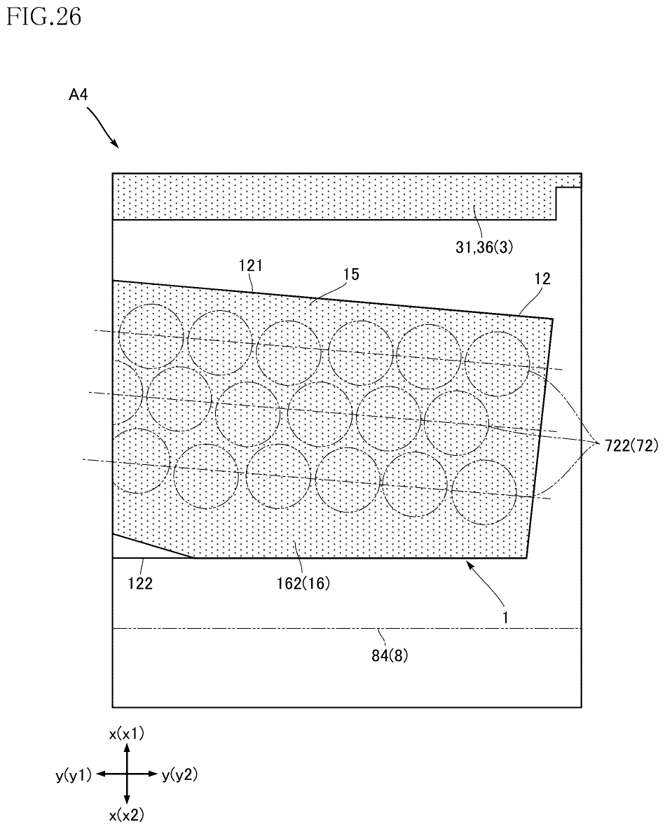

FIGS. 25 and 26 show a semiconductor device according to a fourth embodiment of the present disclosure. In the semiconductor device A4 of the present embodiment, the first area 161 is configured as a single area extending along the x direction, as shown in FIG. 25. The first portion 11 is not provided with the first recess 115. The second area 162 is configured as a single area extending along the y direction, as shown in FIG. 26. The second portion 12 is not provided with the second recess 125.

The present embodiment can also achieve a high current in the semiconductor device A4. As understood from the present variation, the configuration of the first area 161 and the second area 162, or the presence or absence of the first recess 115 and the second recess 125 is not particularly limited.

### Fifth embodiment

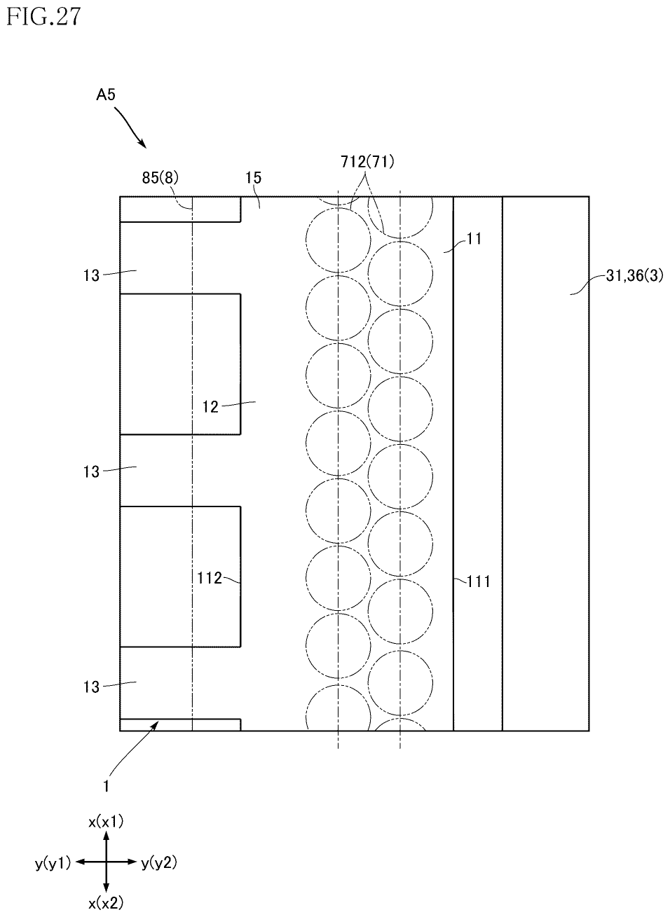

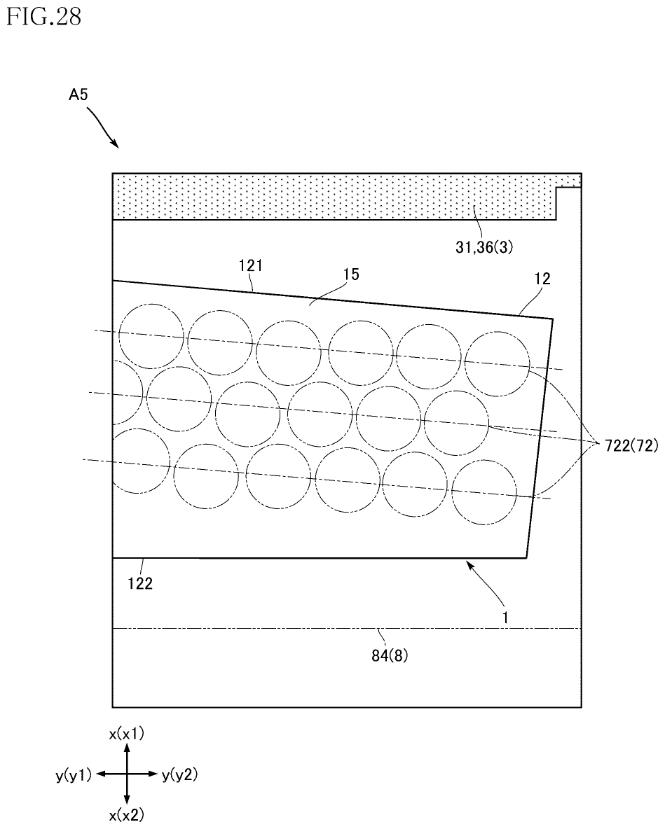

FIGS. 27 and 28 show a semiconductor device according to a fifth embodiment of the present disclosure. In a semiconductor device A5 of the present embodiment, the first lead 1 is not provided with the first metal layer 16. The second bonding portion 712 and the second bonding portion 722 are bonded to the first base material 15. In this case, it is preferable to select materials of the first wire 71, the second wire 72, and the first base material 15 so as to achieve a high-strength bonding between them.

The present embodiment can also achieve a high current in the semiconductor device A5. As understood from the present variation, the presence or absence of the first metal layer 16 and the second metal layer 26 is particularly not limited.

The semiconductor devices according to the present disclosure are not limited to the embodiments described above. The specific configuration of each part of the semiconductor device of the present disclosure may suitably be designed and changed in various manners.

### Sixth Embodiment

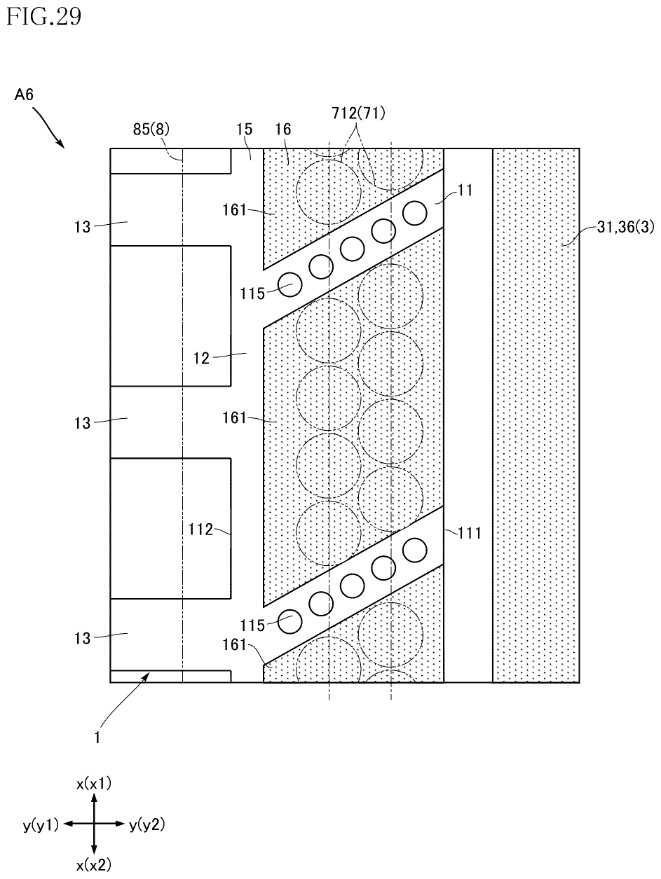

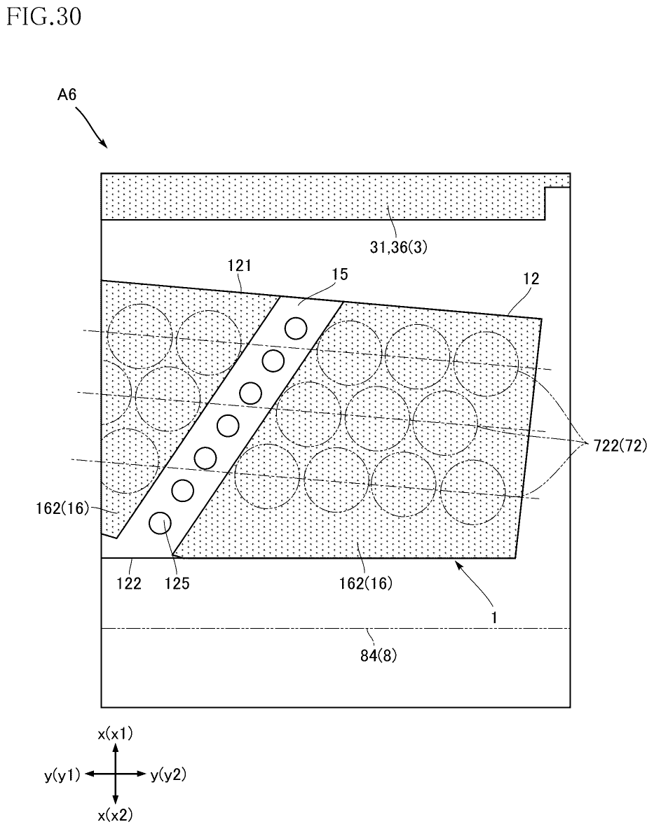

FIGS. 29 and 30 show a semiconductor device according to a sixth embodiment of the present disclosure. In a semiconductor device A6 of the present embodiment, a plurality of first recesses 115 are disposed between adjacent first areas 161, as shown in FIG. 29. The first recesses 115 are arranged parallel (or generally parallel) to the side that faces the first area 161. The shape of the first recess 115 as viewed in the z direction is circular, for example. A plurality of second recesses 125 are disposed between adjacent second areas 162, as shown in FIG. 30. The second recesses 125 are arranged parallel (or generally parallel) to the side that faces the second area 162. The shape of the second recess 125 as viewed in the z direction is circular, for example.

The present embodiment can also achieve a high current n the semiconductor device A6. Further, it is possible to suppress peeling of the first wire 71, the second wire 72, the third wire 73, the fourth wire 74, and the sealing resin 8 from the first lead 1 and the second lead 2. As understood from the present variation, the number, size, shape, and arrangement of the first recess 115 and the second recess 125 are particularly not limited.

### Seventh Embodiment

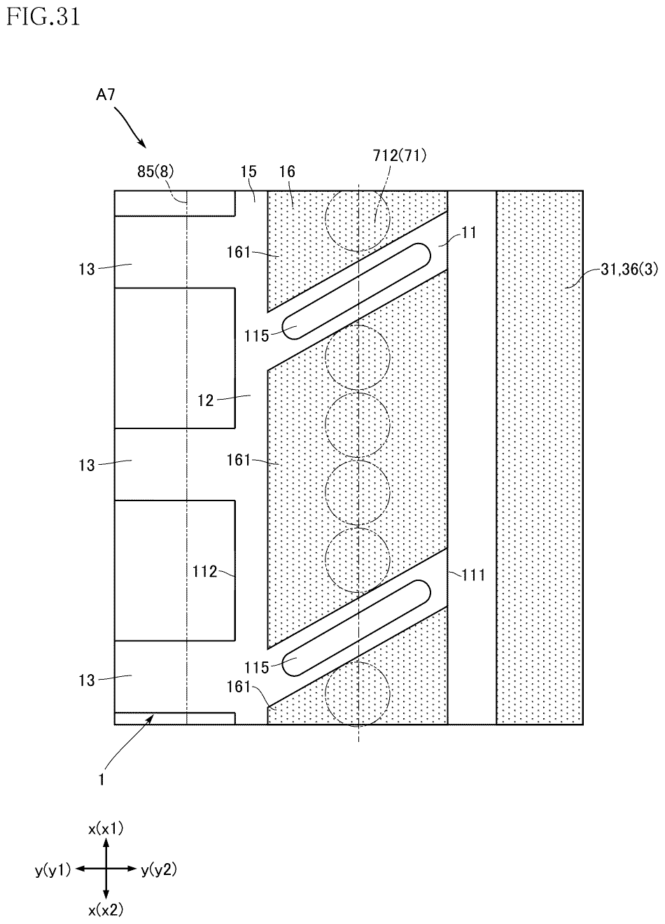

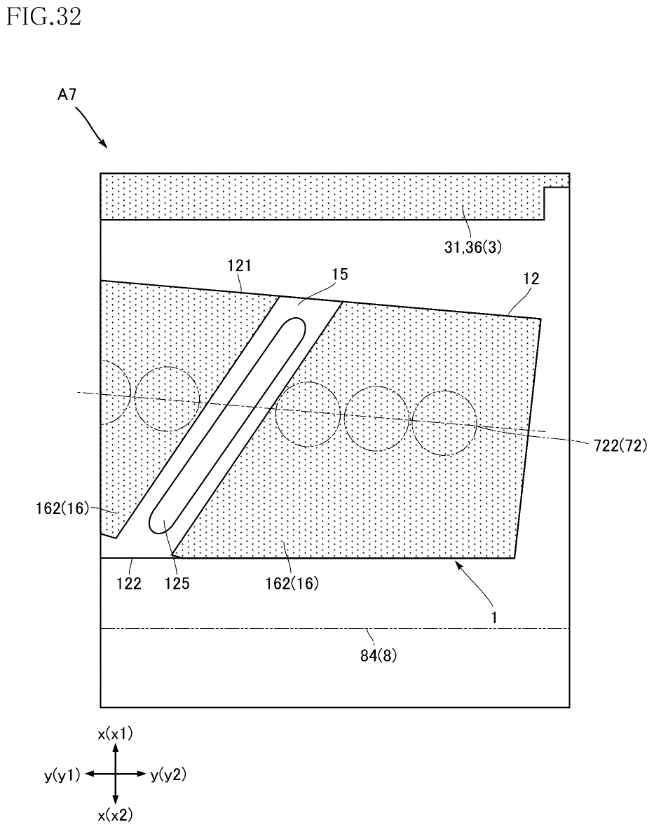

FIGS. 31 and 32 show a semiconductor device according to a seventh embodiment of the present disclosure. In a semiconductor device A7 of the present embodiment, the second bonding portions 712 are arranged in one row. The second bonding portions 722 are arranged in a single row, as shown in FIG. 32.

According to the present embodiment, it is possible to suppress peeling of the first wire 71, the second wire 72, the third wire 73, the fourth wire 74, and the sealing resin 8 from the first lead 1 and the second lead 2. As understood from the present embodiment, the arrangement of the second bonding portions 712 and the second bonding portions 722 is particularly not limited. The present disclosure includes the embodiments described in the following clauses.

### Clause 1A

A semiconductor device comprising:
a first semiconductor element;
a plurality of leads;
a plurality of wires; and
a sealing resin covering the first semiconductor element, the plurality of wires and at least a part of each of the plurality of leads,
wherein the plurality of leads include a first lead,
the plurality of wires include a plurality of first wires each having a first bonding portion connected to the first semiconductor element and a second bonding portion connected to the first lead,
the first lead includes a first portion extending in a first direction orthogonal to a thickness direction of the first semiconductor element, and
the second bonding portions of the plurality of first wires are connected to the first portion and arranged in a plurality of rows along the first direction.

### Clause 2A

The semiconductor device according to clause 1A, wherein the second bonding portions of the plurality of first wires are arranged in a staggered manner.

### Clause 3A

The semiconductor device according to clause 1A or 2A, wherein the plurality of wires includes a plurality of second wires each having a first bonding portion connected to the first semiconductor element and a second bonding portion connected to the first lead,
the first lead includes a second portion extending in a second direction that intersects the first direction as viewed in the thickness direction, and
the second bonding portions of the plurality of second wires are connected to the second portion and arranged in a plurality of rows along the second direction.

### Clause 4A

The semiconductor device according to clause 1A, wherein the second bonding portions of the plurality of second wires are arranged in a staggered manner.

### Clause 5A

The semiconductor device according to any one of clauses 1A to 4A, wherein the first lead includes a plurality of first terminal portions extending in a direction away from the first semiconductor element and protruding from the sealing resin.

### Clause 6A

The semiconductor device according to any one of clauses 1A to 5A, wherein the plurality of leads includes a second lead disposed on an opposite side of the first lead with respect to the first semiconductor element,
the plurality of wires includes a plurality of third wires each having a first bonding portion connected to the first semiconductor element and a second bonding portion connected to the second lead,
the second lead includes a third portion extending in the first direction, and
the second bonding portions of the plurality of third wires are connected to the third portion and are arranged in a plurality of rows along the first direction.

### Clause 7A

The semiconductor device according to clause 6A, wherein the plurality of wires includes a plurality of fourth wires each having a first bonding portion connected to the first semiconductor element and a second bonding portion connected to the second lead,
the second lead includes a fourth portion extending in a third direction that intersects the first direction as viewed in the thickness direction, and
the second bonding portions of the plurality of fourth wires are connected to the fourth portion and are arranged in a plurality of rows along the third direction.

### Clause 8A

The semiconductor device according to clause 7A, wherein the second lead includes a plurality of second terminal portions extending in a direction away from the first semiconductor element and protruding from the sealing resin.

### Clause 9A

The semiconductor device according to clause 7A or 8A, wherein the first semiconductor element includes a first electrode to which the first bonding portions of the plurality of first to fourth wires are connected.

### Clause 10A

The semiconductor device according to clause 9A, wherein the first bonding portions of the plurality of first to fourth wires are discretely arranged as viewed in the thickness direction.

### Clause 11A

The semiconductor device according to clause 9A or 10A, wherein the first semiconductor element is a switching element.

### Clause 12A

The semiconductor device according to any one of clauses 1A to 11A, wherein the plurality of leads includes a third lead on which the first semiconductor element is mounted.

### Clause 13A

The semiconductor device according to clause 12A, further comprising a second semiconductor element mounted on the third lead and electrically connected to the first semiconductor element.

### Clause 14A

The semiconductor device according to any one of clauses 1A to 13A, wherein the first lead includes a first base material and a first metal layer that is laminated on the first base material and to which the second bonding portions of the plurality of first wires are bonded.

### Clause 15A

The semiconductor device according to clause 14A, wherein the first metal layer includes a plurality of first areas arranged along the first direction in the first portion.

### Clause 16

The semiconductor device according to clause 15A, wherein the first base material includes a first recess located between adjacent first areas.

### Clause 17A.

The semiconductor device according to clause 16A, wherein the first recess is a groove extending in a direction that intersects the first direction.

### Clause 1B

A semiconductor device comprising:
a first semiconductor element;
a plurality of leads;
a plurality of wires; and
a sealing resin covering the first semiconductor element, the plurality of wires and at least a part of each of the plurality of leads,
wherein the plurality of leads includes a first lead,
the plurality of wires includes a plurality of first wires each having a first bonding portion connected to the first semiconductor element and a second bonding portion connected to the first lead,
the first lead includes a first portion extending in a first direction orthogonal to a thickness direction of the first semiconductor element,
the second bonding portions of the plurality of first wires are connected to the first portion,
the first lead includes a first base material and a first metal layer that is laminated to the first base material and to which the second bonding portions of the plurality of first wires are bonded, and
the first metal layer includes a plurality of first areas arranged along the first direction in the first portion.

### Clause 2B

The semiconductor device according to clause 1B, wherein the first lead includes a base material containing Cu.

### Clause 3B

The semiconductor device according to clause 2B, wherein the first metal layer contains Ag.

### Clause 4B

The semiconductor device according to any one of clauses 1B to 3B, wherein the plurality of first areas are spaced apart from each other.

### Clause 5B

The semiconductor device according to any one of clauses 1B to 3B, wherein the first metal layer includes a first connection area coupling adjacent first areas.

### Clause 6B

The semiconductor device according to any one of clauses 1B to 5B, wherein the first portion includes a first edge closer to the first semiconductor element and a second edge farther from the first semiconductor element, and
the plurality of first areas are tangential to the first edge.

### Clause 7B

The semiconductor device according to clause 6B, wherein the plurality of first areas are spaced apart from the second edge.

### Clause 8B

The semiconductor device according to any one of clauses 1B or 7B, wherein the first base material includes a first recess located between adjacent first areas.

### Clause 9B

The semiconductor device according to clause 8B, wherein the first recess is a groove extending in a direction intersecting the first direction.

### Clause 10B

The semiconductor device according to any one of clauses 1B to 9B, wherein the plurality of wires includes a plurality of second wires each having a first bonding portion connected to the first semiconductor element and a second bonding portion connected to the first lead,
the first lead includes a second portion extending in a second direction that intersects the first direction as viewed in the thickness direction,
the second bonding portions of the plurality of second wires are connected to the second portion, and
the first metal layer includes a plurality of second areas to which the second bonding portions of the plurality of second wires are connected and arranged along the second direction in the second portion.

### Clause 11B

The semiconductor device according to clause 10B, wherein the plurality of second areas are spaced apart from each other.

### Clause 12B

The semiconductor device according to clause 10B, wherein the first metal layer includes a second connection area coupling adjacent second areas.

### Clause 13B

The semiconductor device according to any one of clauses 10B to 12B, wherein the second portion includes a third edge closer to the first semiconductor element and a fourth edge farther from the first semiconductor element, and
the plurality of second areas are tangential to the third edge.

### Clause 14B

The semiconductor device according to any one of clauses 10B to 13B, wherein the first base material includes a second recess located between adjacent second areas.

### Clause 15B

The semiconductor device according to clause 14B, wherein the second recess is a groove extending in a direction intersecting the second direction.

### Clause 16B

The semiconductor device according to any one of clauses 10B to 15B, wherein the second bonding portions of the plurality of first wires are arranged in a plurality of rows along the first direction.

### Clause 17B

The semiconductor device according to clause 16B, wherein the second bonding portions of the plurality of second wires are arranged in a plurality of rows along the second direction.

### REFERENCE NUMERALS

A1, A2, A3, A31, A4, A5, A6, A7: Semiconductor device
1: First lead 2: Second lead 3: Third lead 8: Sealing resin
11: First portion 12: Second portion 13: First terminal portion
15: First base material 16: First metal layer 21: Third portion
22: Fourth portion 23: Second terminal portion
25: Second base material 26: Second metal layer
31: Island portion 32: Extending portion
35: Third base material 36: Third metal layer
41: Fourth lead 42: Fifth lead 43: Sixth lead 44: Seventh lead
51: First semiconductor element 52: Second semiconductor element
71: First wire 72: Second wire 73: Third wire 74: Fourth wire
75: Fifth wire 76: Sixth wire 77: Seventh wire
81: First resin surface 82: Second resin surface
83: Third resin surface 84: Fourth resin surface
85: Fifth resin surface 86: Sixth resin surface
111: First edge 112: Second edge 115: First recess
121: Third edge 122: Fourth edge 125: Second recess
161: First area 162: Second area 163: First connection area
164: Second connection area 211: Fifth edge 212: Sixth edge
215: Third recess 221: Seventh edge 222: Eighth edge
225: Fourth recess 261: Third area 262: Fourth area
411: Pad portion 412: Terminal portion 421: Pad portion
422: Terminal portion 431: Pad portion 432: Terminal portion
441: Pad portion 442: Terminal portion 511: First electrode
512: Second electrode 521: Electrode 522: Electrode 523: Electrode
711, 721, 731, 741: First bonding portion
712, 722, 732, 742: Second bonding portion
Cp: Capillary z: Thickness direction

1. A semiconductor device comprising:
a first semiconductor element;
a plurality of leads;
a plurality of wires; and
a sealing resin covering the first semiconductor element, the plurality of wires and at least a part of each of the plurality of leads,
wherein the plurality of leads include a first lead,
the plurality of wires include a plurality of first wires each having a first bonding portion connected to the first semiconductor element and a second bonding portion connected to the first lead,
the first lead includes a first portion extending in a first direction orthogonal to a thickness direction of the first semiconductor element, and
the second bonding portions of the plurality of first wires are connected to the first portion and arranged in a plurality of rows along the first direction.

2. The semiconductor device according to claim 1, wherein the second bonding portions of the plurality of first wires are arranged in a staggered manner.

3. The semiconductor device according to claim 1, wherein the plurality of wires includes a plurality of second wires each having a first bonding portion connected to the first semiconductor element and a second bonding portion connected to the first lead,
the first lead includes a second portion extending in a second direction that intersects the first direction as viewed in the thickness direction, and
the second bonding portions of the plurality of second wires are connected to the second portion and arranged in a plurality of rows along the second direction.

4. The semiconductor device according to claim 1, wherein the second bonding portions of the plurality of second wires are arranged in a staggered manner.

5. The semiconductor device according to claim 1, wherein the first lead includes a plurality of first terminal portions extending in a direction away from the first semiconductor element and protruding from the sealing resin.

6. The semiconductor device according to claim 1, wherein the plurality of leads includes a second lead disposed on an opposite side of the first lead with respect to the first semiconductor element,
the plurality of wires includes a plurality of third wires each having a first bonding portion connected to the first semiconductor element and a second bonding portion connected to the second lead,
the second lead includes a third portion extending in the first direction, and
the second bonding portions of the plurality of third wires are connected to the third portion and are arranged in a plurality of rows along the first direction.

7. The semiconductor device according to claim 6, wherein the plurality of wires includes a plurality of fourth wires each having a first bonding portion connected to the first semiconductor element and a second bonding portion connected to the second lead,
the second lead includes a fourth portion extending in a third direction that intersects the first direction as viewed in the thickness direction, and
the second bonding portions of the plurality of fourth wires are connected to the fourth portion and are arranged in a plurality of rows along the third direction.

8. The semiconductor device according to claim 7, wherein the second lead includes a plurality of second terminal portions extending in a direction away from the first semiconductor element and protruding from the sealing resin.

9. The semiconductor device according to claim 7, wherein the first semiconductor element includes a first electrode to which the first bonding portions of the plurality of first to fourth wires are connected.

10. The semiconductor device according to claim 9, wherein the first bonding portions of the plurality of first to fourth wires are discretely arranged as viewed in the thickness direction.

11. The semiconductor device according to claim 9, wherein the first semiconductor element is a switching element.

12. The semiconductor device according to claim 1, wherein the plurality of leads includes a third lead on which the first semiconductor element is mounted.

13. The semiconductor device according to claim 12, further comprising a second semiconductor element mounted on the third lead and electrically connected to the first semiconductor element.

14. The semiconductor device according to claim 1, wherein the first lead includes a first base material and a first metal layer that is laminated on the first base material and to which the second bonding portions of the plurality of first wires are bonded.

15. The semiconductor device according to claim 14, wherein the first metal layer includes a plurality of first areas arranged along the first direction in the first portion.

16. The semiconductor device according to claim 15, wherein the first base material includes a first recess located between adjacent first areas.

17. The semiconductor device according to claim 16, wherein the first recess is a groove extending in a direction that intersects the first direction.

18. A semiconductor device comprising:
a first semiconductor element;
a plurality of leads;
a plurality of wires; and
a sealing resin covering the first semiconductor element, the plurality of wires and at least a part of each of the plurality of leads,
wherein the plurality of leads includes a first lead,
the plurality of wires includes a plurality of first wires each having a first bonding portion connected to the first semiconductor element and a second bonding portion connected to the first lead,
the first lead includes a first portion extending in a first direction orthogonal to a thickness direction of the first semiconductor element,
the second bonding portions of the plurality of first wires are connected to the first portion,
the first lead includes a first base material and a first metal layer that is laminated to the first base material and to which the second bonding portions of the plurality of first wires are bonded, and
the first metal layer includes a plurality of first areas arranged along the first direction in the first portion.

19. The semiconductor device according to claim 18, wherein the first lead includes a base material containing Cu.

20. The semiconductor device according to claim 19, wherein the first metal layer contains Ag.
